(19) United States
(12) Patent Application Publication
(10) Pub. No.: US 2013/0056074 A1
(43) Pub. Date: Mar. 7, 2013

(54) DYE-SENSITIZED SOLAR CELL AND PRODUCTION METHOD OF THE SAME

(71) Applicants: Kazuya ISOBE, Tokyo (JP); Kenichi ONAKA, Tokyo (JP); Takayuki ISHIKAWA, Tokyo (JP)

(72) Inventors: Kazuya ISOBE, Tokyo (JP); Kenichi ONAKA, Tokyo (JP); Takayuki ISHIKAWA, Tokyo (JP)

(73) Assignee: KONICA MINOLTA BUSINESS TECHNOLOGIES, INC., Tokyo (JP)

(21) Appl. No.: 13/596,546

(22) Filed: Aug. 28, 2012

(30) Foreign Application Priority Data
Sep. 5, 2011 (JP) 2011-192452

(51) Int. Cl. H01L 51/46

(52) U.S. Cl. 136/263

(57) ABSTRACT

Disclosed is a dye-sensitized solar cell having at least a substrate, a first electrode, a photoelectric conversion layer containing a semiconductor and a sensitizing dye, a positive hole transporting layer containing a solid positive hole transporting material, and a second electrode, in which the positive hole transporting material contains a polythiophene-based polymer which is a conductive polymer formed via copolymerization of at least 2 compounds having a structure represented by Formula (1), (2), or (3) described in the specification.

This application is based on Japanese Patent Application No. 2011-192452 filed on Sep. 5, 2011, in Japanese Patent Office, the entire content of which is hereby incorporated by reference.

### TECHNICAL FIELD

The present invention relates to a dye-sensitized solar ceil functioning to convert light energy into electrical energy and a production method thereof, and especially, to a dye-sensitized solar cell using a solid material in which as a positive hole transporting material, at least 2 types of polymer precursor are used and a production method of the solar cell.

### BACKGROUND

Photoelectric conversion elements represented by solar cells are elements to convert light energy into electrical energy in order to feed electrical power to devices, and investigations of development of photoelectric conversion elements using inorganic materials represented by silicon have been conventionally conducted. Such inorganic materials include single-crystal silicon, amorphous silicon, and indium copper selenide. In photoelectric conversion elements using an inorganic material, there have been produced productivity problems such that a purification process to form a high-purity inorganic material and a production process to produce a multilayer pn junction structure are required. Further, since rare metal such as indium is used, the problem of the stable supply system of raw materials has been produced.

On the other hand, photoelectric conversion elements using an, organic material in which synthesis makes stable supply possible have also been investigated. For example, an organic photoelectric conversion element in which an electron-conductive (n-type) perylenetetracarboxylic acid and a positive hole-conductive (p-type) copper phthalocyanine are joined has been disclosed (for example, refer to Non-Patent Document 1). It was found out that in such an organic photoelectric conversion element, exciton diffusion length and a space-charge layer needed to be improved, and as a countermeasure therefor, a method has been proposed in which the area of a pn junction region formed using an n-type organic material and a p-type organic material is increased for efficient photoelectric conversion. Specifically, a technique has been proposed in which an n-type electron-conductive material and a p-type positive hole-conductive polymer are combined in a film and thereby the pn-junction region is allowed to increase to carry out photoelectric conversion in the entire film (for example, refer to Non-Patent Document 2). Then, a technique has been proposed in which a conjugated polymer being a positive hole-conductive polymer and fullerene being an electron-conductive material are combined in a film.

However, since the above organic photoelectric conversion elements have exhibited smaller photoelectric conversion efficiency than those using inorganic materials, investigations to enhance photoelectric conversion efficiency have been conducted. As a technique to overcome this problem, attention has been paid to dye-sensitized type photoelectric conversion elements. Specifically, using porous titanium oxide, the semiconductor surface area is allowed to be larger to increase the adsorption amount of an organic sensitizing dye, and thereby photoelectric conversion efficiency is enhanced (for example, refer to Non-Patent Document 3). In this technique, an organic sensitizing dye having been adsorbed on the porous titanium oxide surface is photoexcited and then electrons are injected into titanium oxide by the dye to form dye cations. Then, due to the presence of these dye cations, in the element, via a positive hole transporting layer having an electrolytic solution in which an iodine-containing electrolyte is dissolved in an organic solvent, the cycle of transfer of electrons from the opposite electrode is repeated to realize enhancement of photoelectric conversion efficiency. Further, in this technique, titanium oxide used as a semiconductor was not highly purified and the visible light region with the possibility of photoelectric conversion was expanded to enhance the capability of a dye-sensitized type photoelectric conversion element. On the other hand, since an electrolytic solution was used for the positive-hole transporting layer, attention to prevent chemical species from being dispersed and lost due to liquid leakage was required.

For this problem, a technique relevant to a whole solid dye-sensitized type photoelectric conversion element has been proposed in which as a positive bole transporting material, a solid material such as an amorphous organic positive hole transporting material or copper iodide is used (for example, refer to Non-Patent Documents 4 and 5). There exists a conductive polymer represented by PEDOT polyethylene dioxythiophene) as one of those expected to realize enhanced photoelectric conversion efficiency became of the structure thereof and then investigations thereon have been conducted (for example, refer to Patent Documents 1 and 2 and Non-Patent Document 6).

For example, Patent Document 1 discloses a technique in which a polythiophene being one of the conductive polymers is used as a positive hole transporting material and then using an electrolytic polymerization method or a coating method, a positive hole transporting layer is formed on a semiconductor fine particle-containing layer on which a dye is adsorbed, further, Patent Document 2discloses a technique to produce a solar cell unit in which a coating solution containing polyethylene dioxythiophene, one of the polythiophenes, is coated on a first electrode.

### PRIOR ART DOCUMENTS

Patent Document 1: Unexamined Japanese Patent Application Publication No. 2000-106223

Patent Document 2: Unexamined Japanese Patent Application Publication No, 2011-009419

Non-Patent Document 1: C. W. Tang: Applied Physics Letters, 48, 183 (1986)

Non-Patent Document 2: G. YU, J. Gao, J. C. Humelen, F. Wudland, and A. J. Heeger: Science, 270, 1789 (1996)

Non-Patent Document 3: B. O'Regan and M. Gratzel, Nature, 353, 737 (1991)

Non-Patent Document 4: U. Bach, D. Lupo, P. Comte, J. E. Moser, F. Weissortel, J. Salbeck, H. Spreitzer, and M. Gratzel: Nature, 395, 583 (1998)

Non-Patent Document 5: G. R. A. Kumara, S. Kaneko, M. Kuya, A. Konno, and K. Tennakone: Key Engineering Materials, 119, 228 (2002)

Non-Patent Document 6: J. Xia, N. Masaki, M. Lira-Cantu, Y. Kim, K. Jiang, and S. Yanagida: Journal of the American Chemical Society, 130, 1258 (2008)

### BRIEF DESCRIPTION OF THE INVENTION

As described above, investigations of development of a photoelectric conversion element employing a conductive polymer as a positive hole transporting material have been conducted. However, with advance of the investigations, it came to be found out that even using a conductive polymer, large photoelectric conversion efficiency, having been expected, could not always obtained. In other words, it was found that when the above conductive polymer such as PEDOT was used as a positive hole transporting material, in the initial stage, large conversion efficiency was obtained, being, however, significantly decreased over time, and thereby the problem of stably maintaining the photoelectric conversion efficiency over a long term has been noted.

To solve the above problems, the present invention was completed and an object thereof is to provide a dye-sensitized solar cell capable of realizing enhanced photoelectric conversion efficiency and of stably maintaining the photoelectric conversion efficiency at a high level in which a conductive polymer formed from a polythiophene-based polymer is used as the positive hole transporting material; and a production method of the solar cell.

The present invention will now briefly be described.

A dye-sensitized solar cell having at least a substrate, a first electrode, a photoelectric conversion layer containing a semiconductor and a sensitizing dye, a positive hole transporting layer containing a solid positive hole transporting material, and a second electrode, wherein the positive hole transporting material contains a polythiophene-based polymer and the polythiophene-based polymer is a conductive polymer formed via copolymerization of at least 2 compounds having a structure represented by Formula (1), (2), or (3).

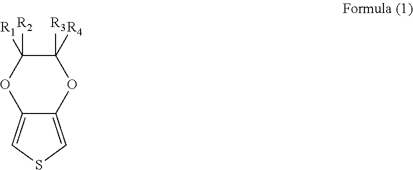

Wherein, R₁ to R₄ represent any of a hydrogen atom, a halogen atom, an alkyl group, a cycloalkyl group, an alkoxy group, a polyethylene oxide group, and an aryl group; any of the groups may be further substituted, and R₁ to R₄ may be same or different.

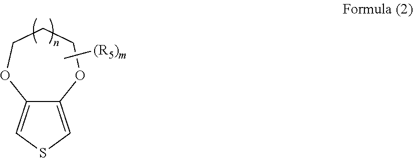

Wherein, R₅ represents any of a hydrogen atom, a halogen atom, an alkyl group, an alkoxy group, a polyethylene oxide group, and an aryl group; any of the groups may be further substituted, n represents an integer of 1 or 2; and m represents an integer of 2n+4.

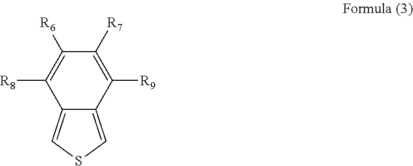

Wherein, R₆ to R₉ represent any of a hydrogen atom, a halogen atom, an alkyl group, an alkoxy group, a polyethylene oxide group, find an aryl group; any of the groups may be further substituted, and R₆ to R₉ may be same or different.

At least one of R₁ to R₄ in a compound having the structure represented by Formula (1) is preferably any of an alkyl group or a cycloalkyl group having 6 to 14 carbon atoms, an aryl group having at least 6 carbon atoms, and an alkyl group having an oxyethylene group.

At least one of R₁ to R₄ is more preferably either of an alkyl group having 6 to 14 carbon atoms and an aryl group having at least 6 carbon atoms.

At least one of R₁ to R₄ is specifically preferably an alkyl group having 6 to 14 carbon atoms.

R₅ in a compound having the structure represented by Formula (2) is preferably any of a hydrogen atom, an alkyl group or a cycloalkyl group having 6 to 14 carbon atoms, an aryl group having at least 6 carbon atoms, and an alkyl group having an oxyethylene group; and n is preferably 1.

R₅ is more preferably either of a hydrogen atom, an alkyl group having 6 to 14 carbon atoms and an aryl group having at least 6 carbon atoms.

R₅ is specifically preferably a hydrogen atom, an alkyl group having 6 to 14 carbon atoms.

At least one of R₆ to R₉ in a compound having the structure represented by Formula (3) is preferably any of an alkyl or a cycloalkyl group having 6 to 14 carbon atoms, an aryl group having at least 6 carbon atoms, and an alkyl group having an oxyethylene group.

At least one of R₆ to R₉ is more preferably either of an alkyl group having 6 to 14 carbon atoms and an aryl group having at least 6 carbon atoms.

At least one of R₆ to R₉ is specifically preferably an alkyl group having 6 to 14 carbon atoms.

The above-mentioned dye-sensitized solar cell is preferably produced via a heating step after at least the photoelectric conversion layer and the positive hole transporting layer are formed.

The temperature of the heating treatment carried out after formation of the photoelectric conversion layer and the positive hole transporting layer is preferably 70° to 150° C.

In the present invention, as a solid positive hole transporting material contained in a positive hole transporting layer, a conductive polymer formed via copolymerization of compounds having at least 2 types of structure differing from each other is used and thereby photoelectric conversion efficiency can be stably maintained at a high level.

### BRIEF DESCRIPTION OF THE DRAWINGS

FIG. 1 is a schematic cross-sectional view showing one example of a dye-sensitized solar cell according to the present invention; and

FIG. 2a and FIG. 2b are schematic views showing the relationship between the numerical value of “form factor FF” and the shape of “a voltage-current characteristic graph.”

### PREFERRED EMBODIMENT OF THE INVENTION

The present invention relates to a dye-sensitized solar cell having a photoelectric conversion layer containing a semiconductor and an organic sensitizing dye, and especially, to a dye-sensitized solar cell using a conductive polymer containing a polythiophene-based polymer as a positive hole transporting material and a production method of the solar cell.

In the technique of the dye-sensitized solar cell, to enhance photoelectric conversion efficiency, a technique to use a conductive polymer as the positive hole transporting material has been investigated. However, the problem that the photoelectric conversion efficiency was difficult to stably maintain at a high level has been posed. With respect to the reason why the photoelectric conversion efficiency of a dye-sensitized solar cell using a conductive polymer as the positive hole transporting material is difficult to stably maintain at a high level, the present inventors presumed as follows.

Initially, in a conductive polymer used as the positive hole transporting material for a dye-sensitized solar cell, conventionally, one type of polymer precursor has been used to form a positive hole transporting layer via an electrolytic polymerization method or a thermal polymerization method. It is conceivable that PEDOT, which is one type of polythiophene-based polymer well known as a conductive polymer, exhibits enhanced crystallizability to obtain enhanced positive hole transporting capability and thereby excellent performance as the positive hole transporting material can be realized; but on the contrary, due to its enhanced crystallizability, it is difficult to release distortion and stress caused by heat, resulting in easy occurrence of cracks. In a dye-sensitized solar cell, due to temperature changes resulting from environmental variations and repetition of a redox cycle, a conductive polymer used as the positive hole transporting material is thought to always deform in its molecular level and thereby it is thought that due to the decrease of the positive hole transporting capability resulting from crack occurrence, stable photoelectric conversion efficiency cannot be maintained.

The present inventors thought, from the above presumption, that when a conductive polymer used as the positive hole transporting material is inhibited from crack occurrence, the photoelectric conversion efficiency could be stably maintained at a high level. Specifically, it was thought that when as a solid positive hole transporting material contained in the positive hole transporting layer, a conductive polymer formed via copolymerization of compounds having at least 2 types of structure differing from each other was used, crystallizability could be suppressed low and then cracks caused by heat or redox repetition could not tend to occur. Then, investigations were continued and as a result, it was found out that when a dye-sensitized solar cell having the above configuration was formed, the above-mentioned problems were solved.

The present invention will now be detailed.

### Structure of a Dye-Sensitized Solar Cell

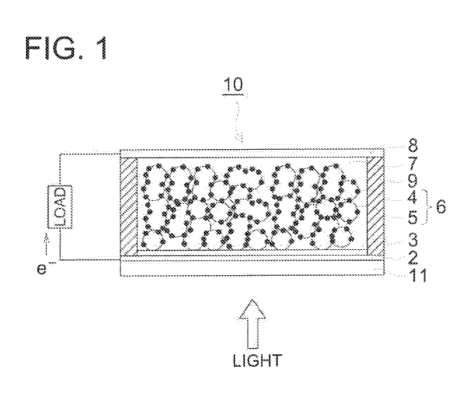

Initially, the structure of a dye-sensitized solar cell according to the present invention will be described with reference to FIG. 1. FIG. 1 is a schematic cross-sectional view showing one example of the structure of the dye-sensitized solar cell according to the present invention.

The dye-sensitized solar cell 10 shown in FIG. 1 is constructed of a substrate 1, a first electrode 2, a photoelectric conversion layer 6, a positive hole transporting layer, a second electrode 8, and a dividing wall 9. As shown by the arrow of the figure, light is allowed to enter the photoelectric conversion layer 6 from the side where the substrate 1 and the first electrode 2 are arranged. Further, the photoelectric conversion layer 6 contains a semiconductor 5 and a sensitizing dye 4, and the positive hole transporting layer 7 contains a conductive polymer represented by a compound to be described later as the positive hole transporting material. Between the first electrode 2 and the photoelectric conversion layer 6, a barrier layer 3 is provided for preventing short circuit occurrence and for sealing. Still further, a UV absorbing layer 11 may be provided on the substrate 1.

(Mechanism of Electric Flow in a Solar Cell)

The dye-sensitized solar cell 10 carries out photoelectric conversion based on the following procedures to function as a cell. Namely, (1) light is irradiated to the first electrode 2 and thereby a sensitizing dye contained in the photoelectric conversion layer 6 absorbs the light to emit electrons. At this moment, the sensitizing dye becomes an oxide. (2) Electrons having been emitted from, the sensitizing dye move to a semiconductor in the photoelectric conversion layer 6 and further move to the first electrode 2 from the semiconductor. (3) Electrons having moved to the first electrode 2 travel to the second electrode 8 serving as the opposite electrode to reduce a positive hole transporting material at the second electrode 8. (4) The above sensitizing dye oxide receives electrons from the reduced positive hole transporting material to return to the original state (the sensitizing dye). (5) (1) to (4) described above are repeated and thereby electrons are repetitively moved from the first electrode 2 to the second electrode 8 to allow electricity to flow.

In this manner, in the dye-sensitized solar cell 10 of FIG. 1, light irradiation allows a sensitizing dye to become in an excited state to emit electrons and then the emitted electrons are passed through a semiconductor to reach the first electrode 2 for flowing to the outside. On the other hand, the sensitizing dye having become an oxide via emission of electrons receives electrons, fed from the second electrode 8, from the positive hole transporting layer to return to the original state. The above mechanism permits electrons to move in order to realize the function as a cell.

The dye-sensitized solar cell 10 according to the present invention contains a “conductive polymer” which is a solid material in which in the positive hole transporting layer 7, at least 2 types of polymerization precursor are used as the positive hole transporting material. A “positive hole transporting layer containing a conductive polymer serving as a solid positive hole transporting material” constituting the dye-sensitized solar cell according to the present invention will now be described.

### Description of a Positive Hole Transporting Layer

Initially, a positive hole transporting layer attaining a “conductive polymer,” which is a solid material, as a positive hole transporting material is described below. The positive hole transporting layer 7 provided in the dye-sensitized solar cell 10 shown in FIG. 1 allows positive holes to move toward the second electrode 8 from a sensitizing dye having been in an excited state via light absorption, followed by emission of electrons to reduce the sensitizing dye to be stabilized. In other words, the positive hole transporting layer 7 receives electrons from the second electrode 8 and then passes the received electrons to the sensitizing dye having been in the excited state in the photoelectric conversion layer 6 to allow the sensitizing dye to return to the state prior to light irradiation.

(Effects of Use of a Conductive Polymer as the Positive Hole Transporting Material)

In the present invention, since a conductive polymer is used as the positive hole transporting material, there occurs no liquid leakage which has been apprehended in a dye-sensitized solar cell employing an electrolytic solution as the positive hole transporting material. Further, since a conductive polymer in which positive holes are structurally easy to move is used as the positive hole transporting material, in the positive hole transporting layer, electrons are stably transferred to an excited-state sensitizing dye from the second electrode 8 to contribute to exerting enhanced photoelectric conversion efficiency. Especially, in the present invention, a conductive polymer formed via copolymerization of at least 2 types of polymerization precursor having a structure represented by Formula (1), (2), or (3) to be described later is used, and thereby crack occurrence is inhibited and the stability of the photoelectric conversion efficiency is improved.

(Conductive Polymers)

The conductive polymer used in the present invention is a conductive polymer obtained from at least 2 types of compound having a structure represented by Formula (1), (2), or (3) in the molecule. The conductive polymer belongs to a polymer referred to as a polythiophene having a heterocyclic structure (sulfur-containing heterocyclic structure) containing sulfur atoms in its main chain. Of polythiophenes, a polymer formed via polymerization of at least 2 types of compound having a structure represented by Formula (1), (2), or (3) has a side chain structure, in addition to a conjugated main chain structure in which a double bond and a single bond contributing to charge transfer are alternately arranged. It is conceivable that the presence of this side chain structure improves the crystallizability of a molecule and contributes to enhancing photoelectric conversion efficiency. Namely, it is conceivable that when a site capable of exerting intermolecular interactions is present in the molecular structure, a formed conductive polymer is regularly arranged, which allows segment movements due to heat to be hard to occur to form a positive hole transporting layer having a stable structure. Further, it is conceivable that the exertion of such molecular interactions also reduces the chance of permitting the semiconductor and the positive hole transporting layer to come close to each other. The conductive polymer of the present invention can be synthesized via copolymerization of at least 2 types of compound, i.e., polymerization precursor, having a structure represented by Formula (1), (2), or (3).

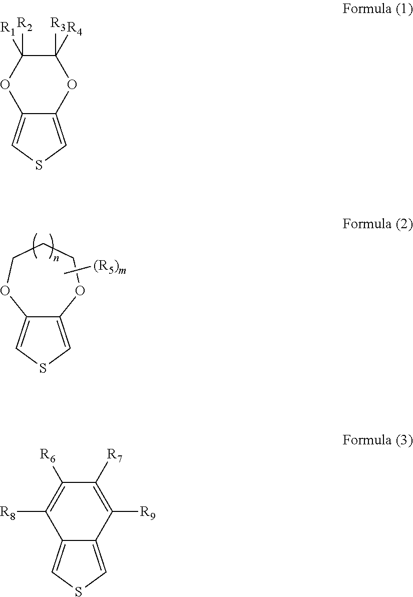

wherein R₁ to R₄ in a compound having the structure represented by Formula (1) represent any of a hydrogen atom, a halogen atom, an alkyl group, a cycloalkyl group, an alkoxy group, a polyethylene oxide group, and an aryl group; any of the groups may be further substituted; and R₁ to R₄may be same or different.

R₅ in a compound having the structure represented by Formula (2) represents any of a hydrogen atom, a halogen atom, an alkyl group, an alkoxy group, a polyethylene oxide group, and an aryl group; n in the structure represents an integer of 1 or 2; m represents an integer of 2n+4; and any of the groups may be further substituted.

Further, R₆ to R₉ in a compound having the structure represented by Formula (3) represent any of a hydrogen atom, a halogen atom, an alkyl group, an alkoxy group, a polyethylene oxide group, and an aryl group; any of the groups may be further substituted; and R₆ to R₉ may be same or different.

The halogen atom represented by R₁ to R₄ in a compound having the structure represented by Formula (1), R₅ in a compound having the structure represented by Formula (2), and R₆ to R₉ in a compound having the structure represented by Formula (3) includes a chlorine atom, a bromine atom, a fluorine atom. Further, the alkyl group includes methyl, ethyl, propyl, isopropyl, tert-butyl, pentyl, hexyl, octyl, dodecyl, tridecyl, tetradecyl, and pentadecyl groups. The cycloalkyl group represented by R₁ to R₄ in a compound having the structure represented by Formula (1) includes a cyclopentyl group and a cyclohexyl group.

The alkoxy group represented by R₁ to R₄ in a compound having the structure represented by Formula (1), R₅ in a compound having the structure represented by Formula (2), and R₆ to R₉ in a compound having the structure represented by Formula (3) includes a methoxy group, an ethoxy group, a propoxy group, and a butoxy group. Further, the polyethylene oxide group includes a methoxyethoxy group and a methoxyethoxyethoxy group, and the aryl group includes a phenyl group, a naphthyl group, and an anthracenyl group.

Specific examples of the compound having the structure represented by Formula (1) are shown below.

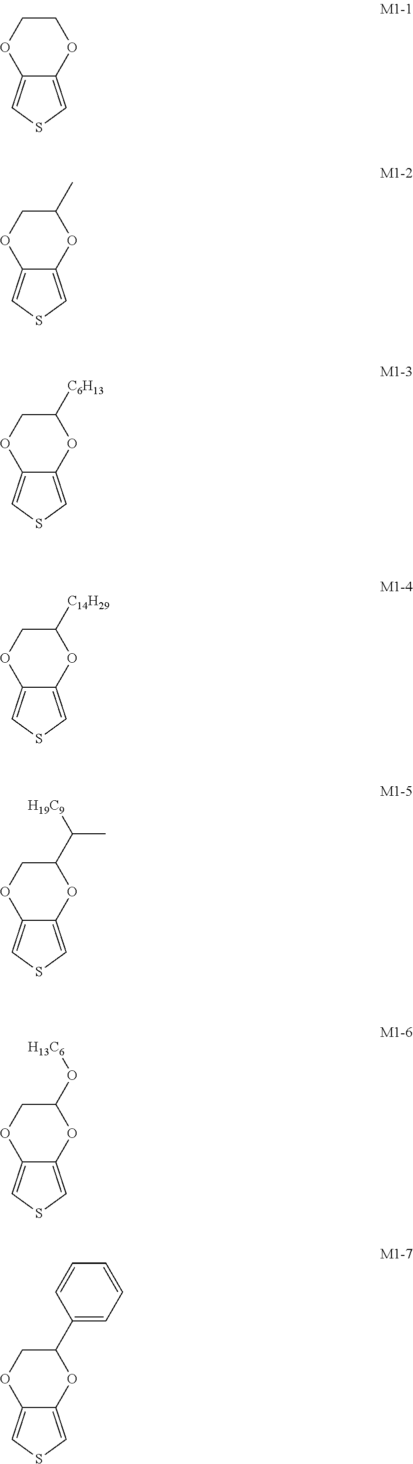

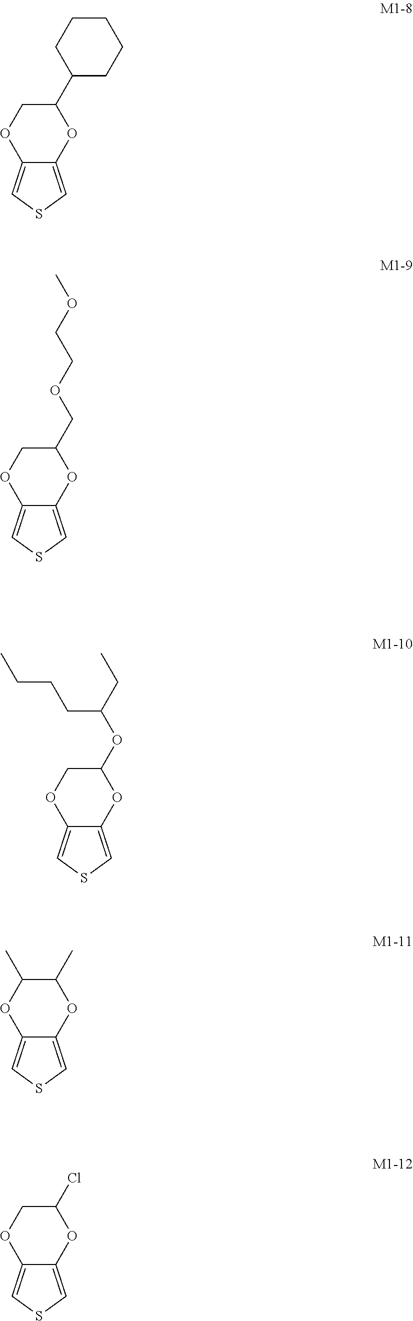 [SMILES: c1scc2c1OCC(C1CCCCC1)O2 ; COCCOCC1COc2cscc2O1 ; CCCCC(CC)OC1COc2cscc2O1 ; CC1Oc2cscc2OC1C ; ClC1COc2cscc2O1]

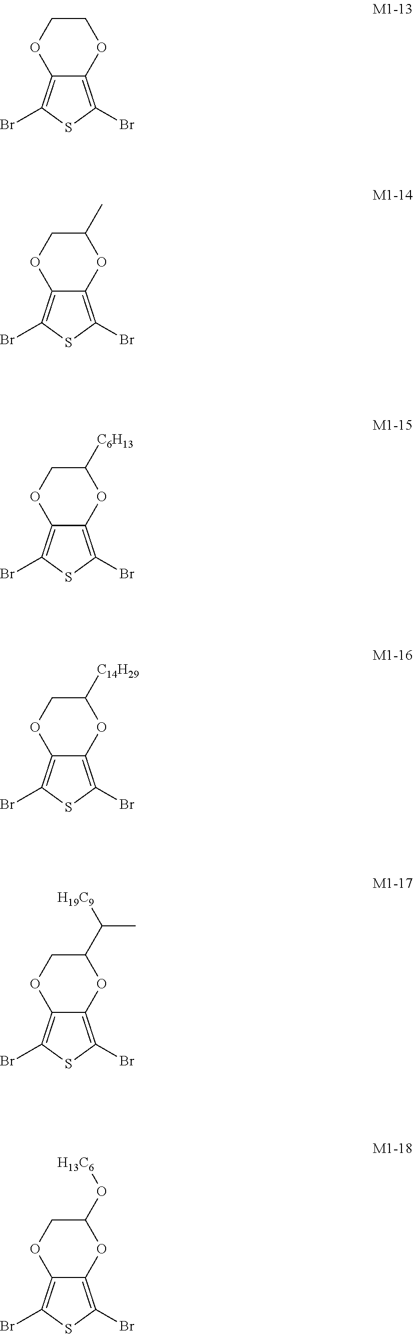

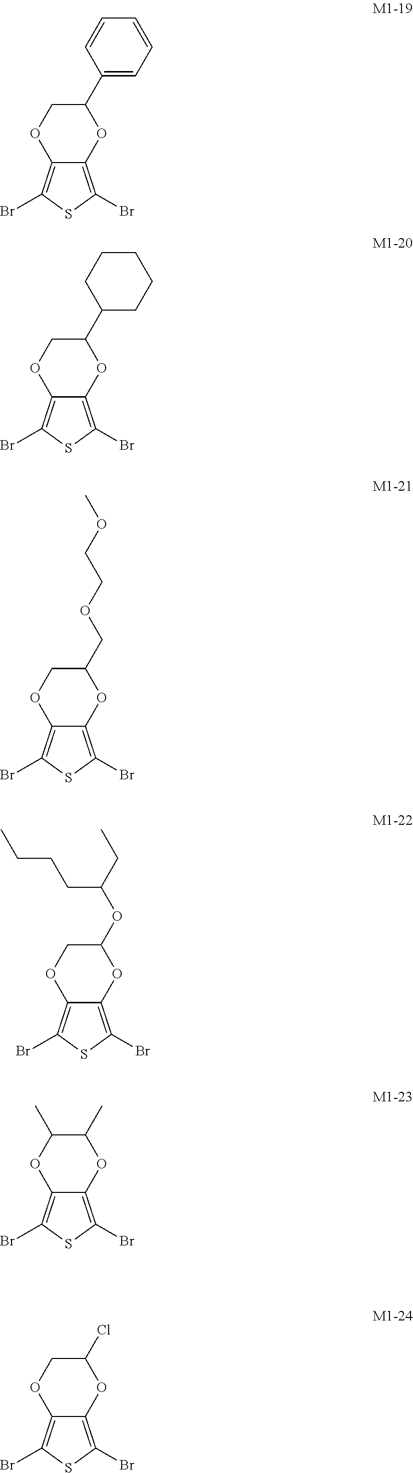

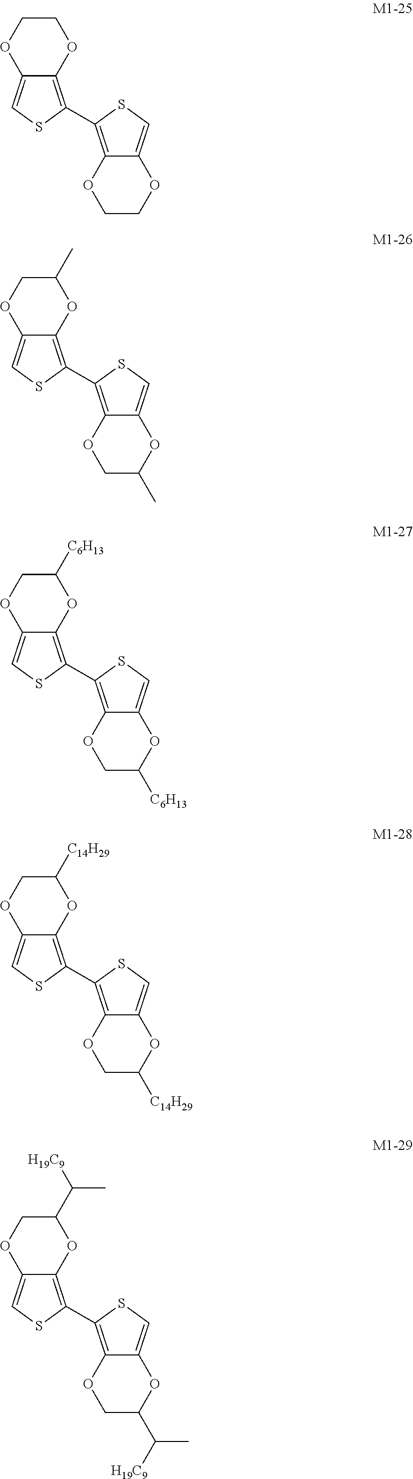

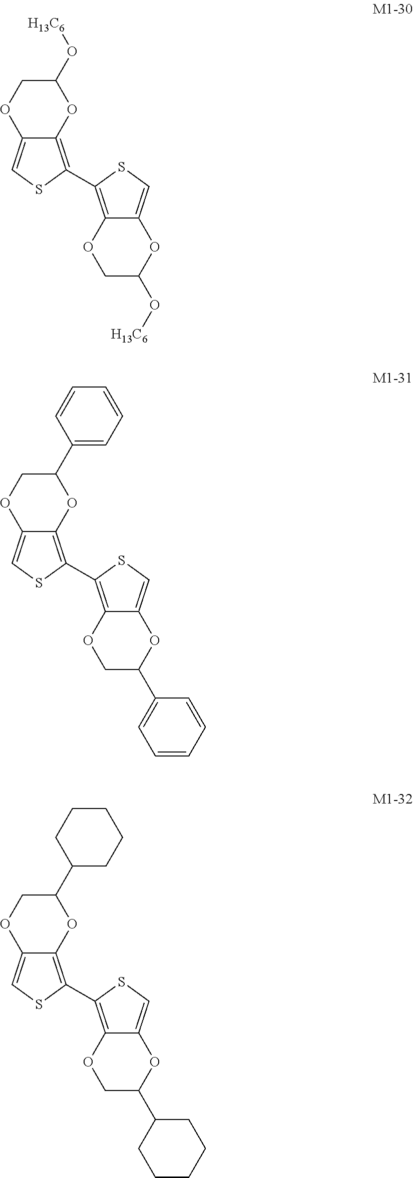

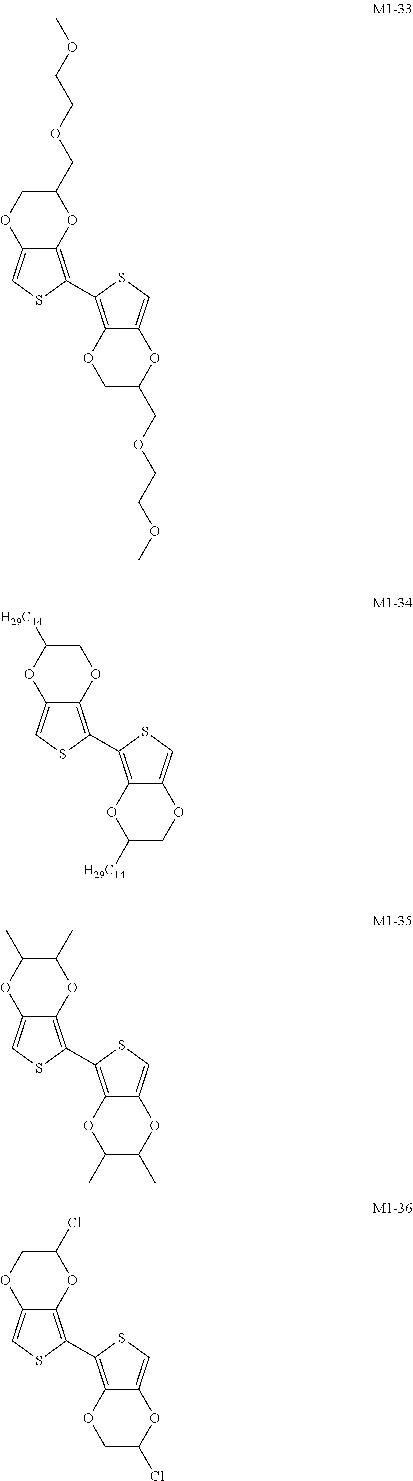

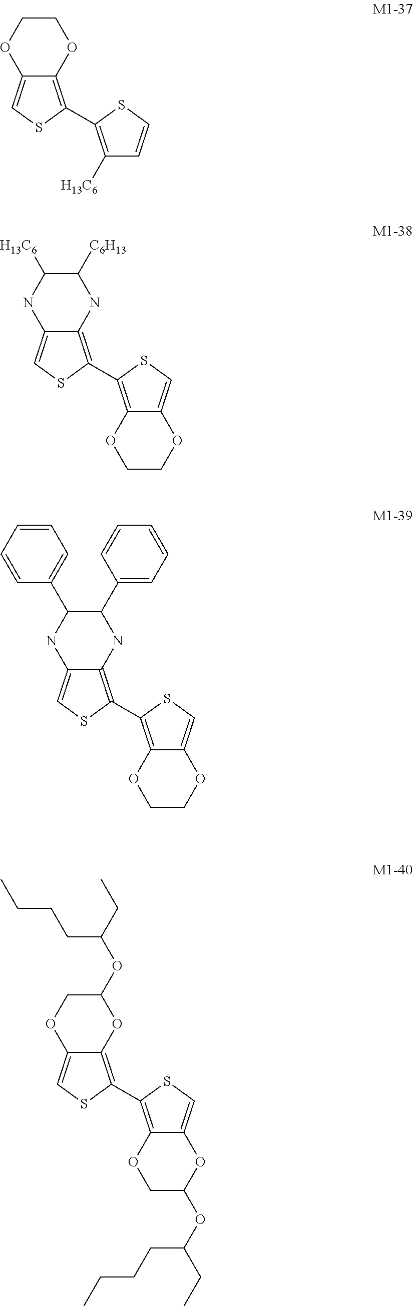

Specific examples of the compound having the structure represented by Formula (2) are shown below.

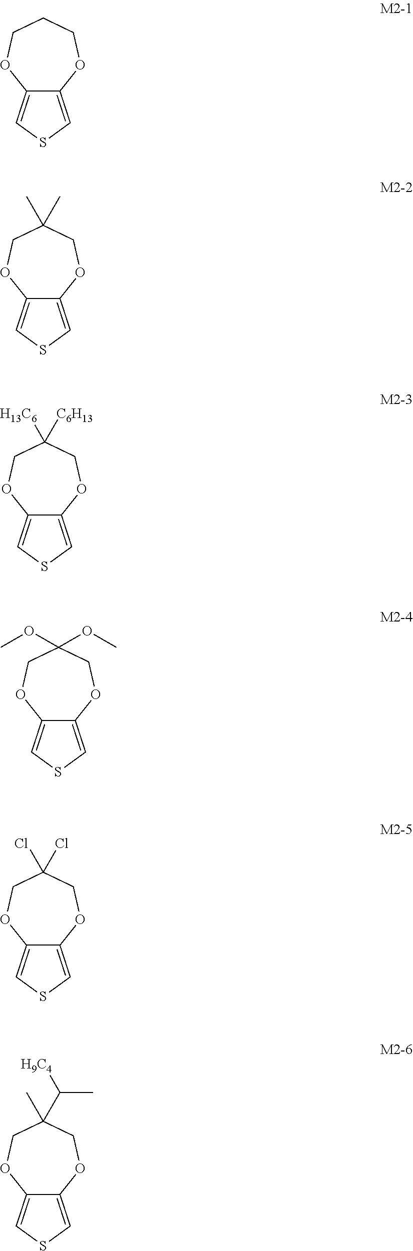

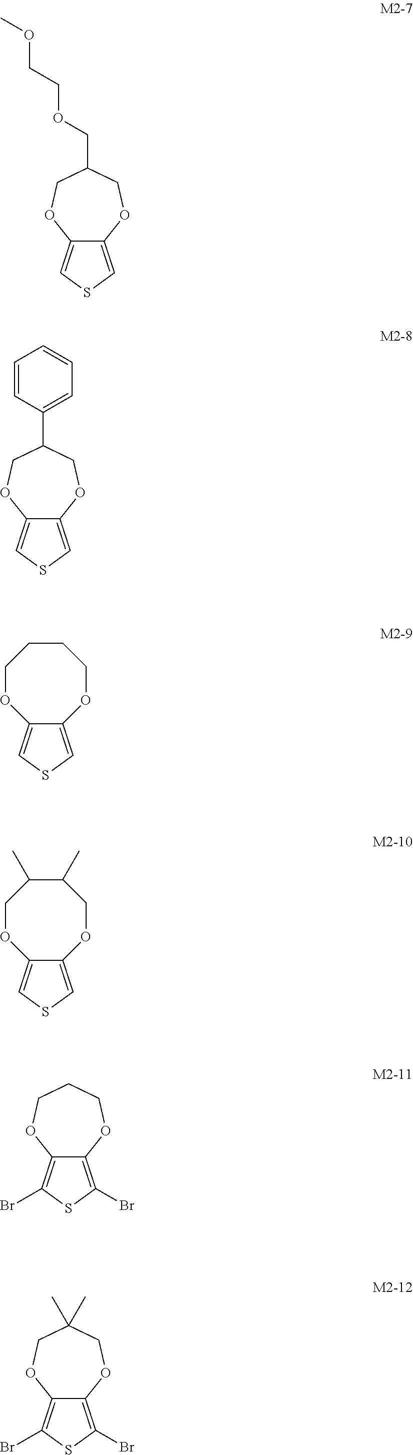 [SMILES: COCCOCC1COc2cscc2OC1 ; c1ccc(C2COc3cscc3OC2)cc1 ; c1scc2c1OCCCCO2 ; CC1COc2cscc2OCC1C ; Brc1sc(Br)c2c1OCCCO2 ; CC1(C)COc2c(Br)sc(Br)c2OC1]

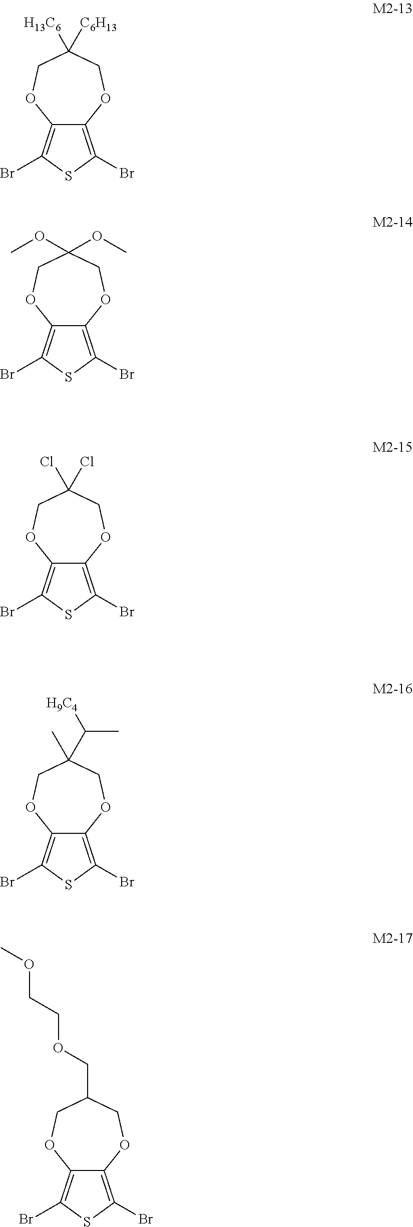

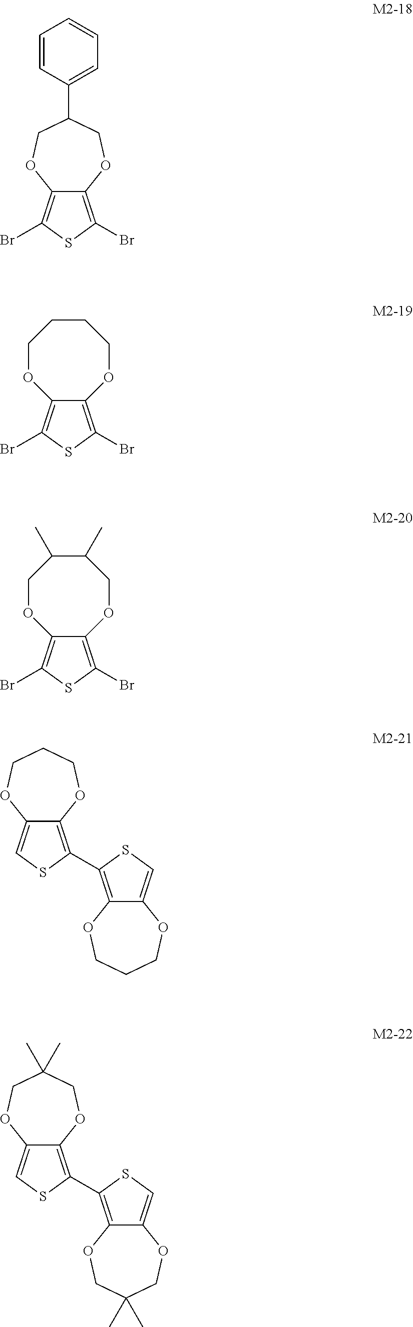 [SMILES: Brc1sc(Br)c2c1OCC(c1ccccc1)CO2 ; Brc1sc(Br)c2c1OCCCCO2 ; CC1COc2c(Br)sc(Br)c2OCC1C ; c1sc(-c2scc3c2OCCCO3)c2c1OCCCO2 ; CC1(C)COc2csc(-c3scc4c3OCC(C)(C)CO4)c2OC1]

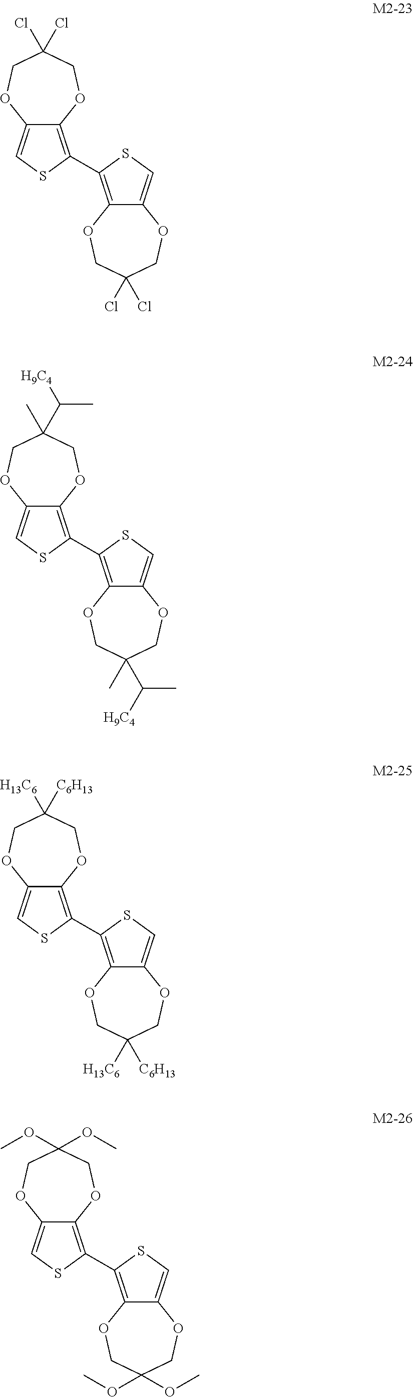

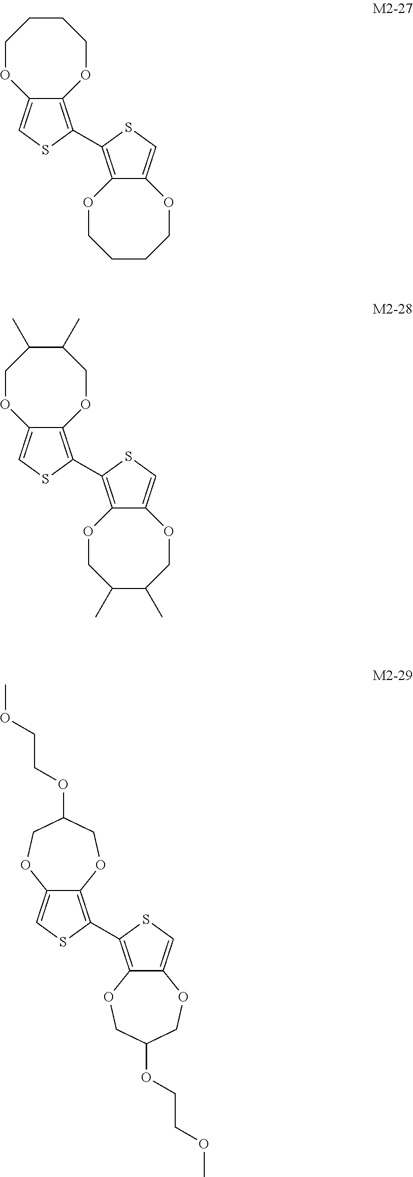 [SMILES: c1sc(-c2scc3c2OCCCCO3)c2c1OCCCCO2 ; CC1COc2csc(-c3scc4c3OCC(C)C(C)CO4)c2OCC1C ; COCCOC1COc2csc(-c3scc4c3OCC(OCCOC)CO4)c2OC1]

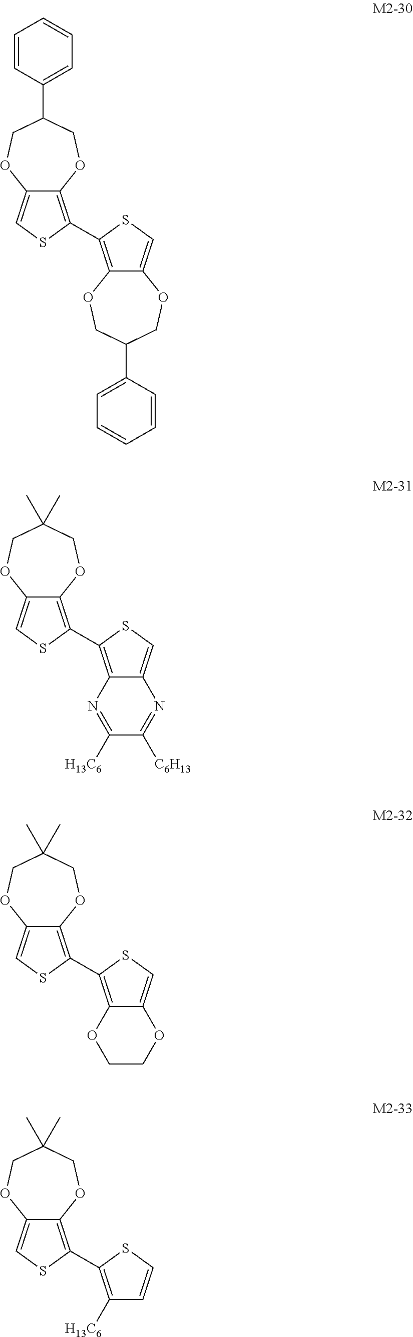

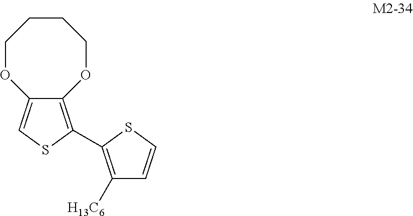

Specific examples of the compound having the structure represented by Formula (3) are shown below.

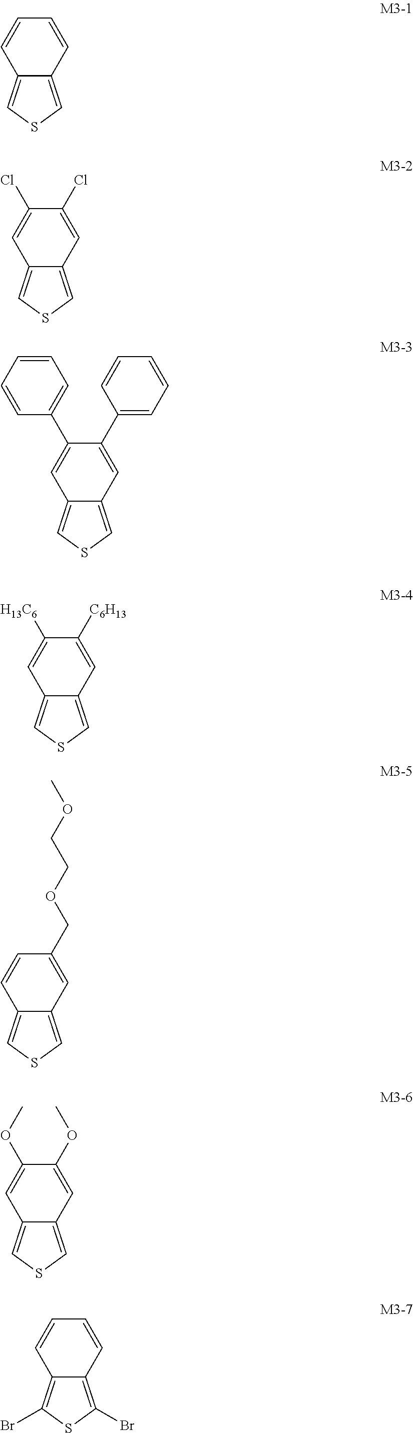

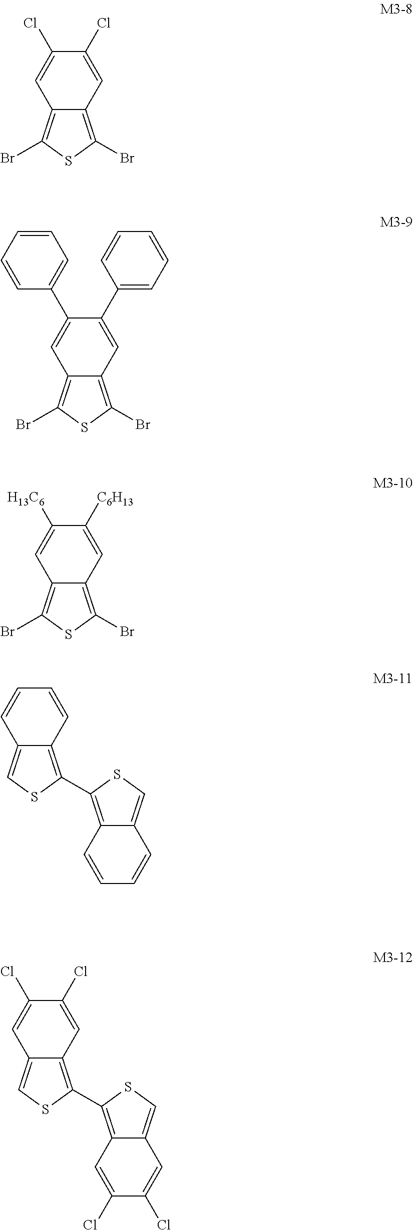

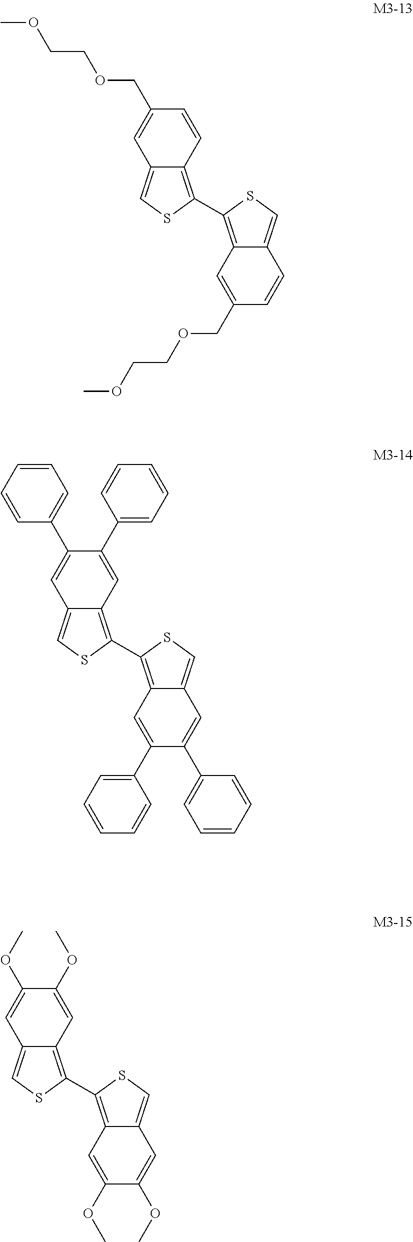 [SMILES: COCCOCc1ccc2c(-c3scc4ccc(COCCOC)cc34)scc2c1 ; c1ccc(-c2cc3csc(-c4scc5cc(-c6ccccc6)c(-c6ccccc6)cc45)c3cc2-c2ccccc2)cc1 ; COc1cc2csc(-c3scc4cc(OC)c(OC)cc34)c2cc1OC]

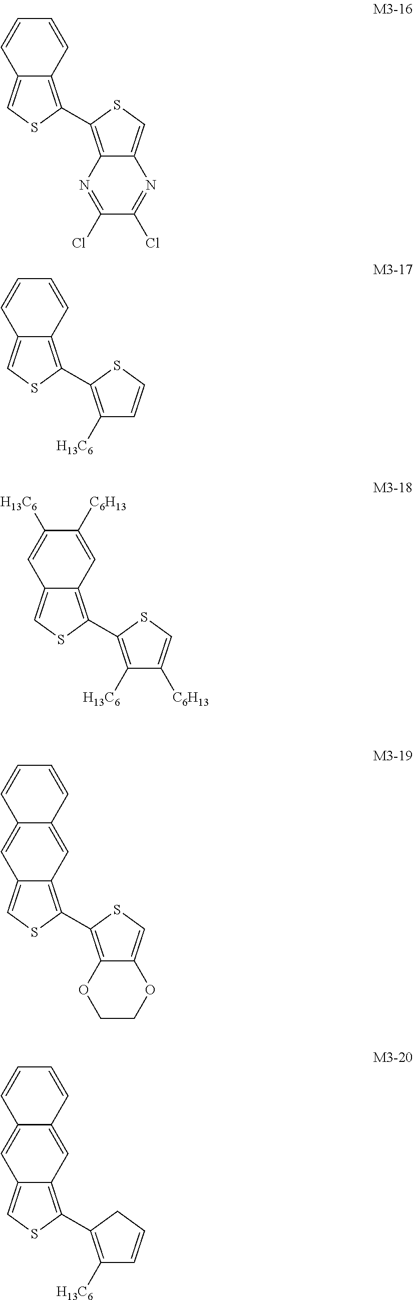

In the present invention, of compounds having a structure represented by Formula (1), (2), or (3) to form a conductive polymer referred to as a polythiophene, a compound having a functional group described below is preferably used.

Preferable are those in which at least one of R₁ to R₄ in a compound having a structure represented by Formula (1) is any of an alkyl group or a cycloalkyl group having 6 to 14 carbon atoms, an aryl group having at least 6 carbon atoms, and a group in which a polyethylene oxide group and a methoxy group are combined. Of these, either of an alkyl group having 6 to 14 carbon atoms and an aryl group having at least 6 carbon atoms is more preferable, and an alkyl group having 6 to 14 carbon atoms is specifically preferable.

Preferable are those in which R₅ in a compound having a structure represented by Formula (2) is any of an alkyl group or a cycloalkyl group having 6 to 14 carbon atoms, an aryl group having at least 6 carbon atoms, and an alkyl group having an oxyethylene group; and n is 1. Of these, R₅ is more preferably either of an alkyl group having 6 to 14 carbon atoms and an aryl group having at least 6 carbon atoms, being specifically preferably an alkyl group having 6 to 14 carbon atoms.

Preferable are those in which at least one of R₆ to R₉ in a compound having a structure represented by Formula (3) is any of an alkyl group or a cycloalkyl group having 6 to 14 carbon atoms, an aryl group having at least 6 carbon atoms, and a group in which a polyethylene oxide group and a methoxy group are combined. Of these, either of an alkyl group having 6 to 14 carbon atoms and an aryl group having at least 6 carbon atoms is more preferable, and an alkyl group having 6 to 14 carbon atoms is specifically preferable.

A conductive polymer is obtained via polymerization of at least 2 types of compound each having a structure represented by Formula (1), (2), or (3) in the molecule. At least 2 types of compound having a structure represented by Formula (1), at least 2 types of compound having a structure represented by Formula (2), or at least 2 types of compound having a structure represented by Formula (3) may be polymerized.

A dye-sensitized solar cell, in which a conductive polymer formal via copolymerization of at least 2 types of such preferable compound is used as the positive hole transporting material, exhibits enhanced photoelectric conversion efficiency. The reason is thought to be that the above functional group to specifically facilitate intermolecular interactions is present in side chains, and thereby even with the influence of heat, these intermolecular interactions strongly inhibit molecular chain segment movements, resulting in inhibition of crack occurrence.

The polymerization method of a compound having a structure represented by Formula (1), (2), or (3) includes, for example, the method described in. J. R, Reynolds et al: Adv. Mater., 11, 1379 (1999).

(Forming Method of a Positive Hole Transporting Layer)

A positive hole transporting layer containing, as a solid positive hole transporting material, a conductive polymer formed using a compound having a structure represented by Formula (1), (2), or (3) can be produced by a well known method. Formation thereof is carried out, for example, via an electrolytic polymerization method or a chemical polymerization method in the presence of a polymerization catalyst, being preferably carried out via an electrolytic polymerization method.

An electrolytic polymerization solution used for electrolytic polymerization is obtained by dissolving a monomer constituting a polymer having a repeating unit represented by Formulas (1) to (3) or a dimer thereof and a supporting electrolyte in a solvent. Examples of the solvent include acetonitrile, tetrahydrofuran, propylene, carbonate, dichloromethane, o-dichloiobenzene, and dimethylformamide. Examples of the supporting electrolyte includes salts such as lithium perchlorate, lithium tetrafluoroborate, tetrabutylammonium perchlorate, and Li[(CH₃SO₂)₂N]. The concentration of the monomer or the dimer thereof in the electrolytic polymerization solution is preferably about 0.1 to 1,000 mmol/L and the concentration of the supporting electrolyte is preferably about 0.1 to 2 mo/L.

In an electrolytic polymerization solution, a substrate (a semiconductor electrode) having a porous semiconductor layer carrying a dye is immersed. Then, the semiconductor electrode, a platinum plate, and Ag/AgCl are used as a working electrode, an opposite electrode, and a reference electrode, respectively, for direct electrolysis. The current density is preferably 0.01 to 1000 μA/cm², more preferably 1 to 500 μA/cm². The temperature of the solution may fall within the range where the solvent will not be solidified or undergo bumping and is commonly about −30 to +80° C. Conditions such as the application voltage, the current density, and the electrolysis duration are set based on the types of a monomer and a solvent used and the thickness of a formed semiconductor layer.

The polymerization degree of a polymer is confirmed by a solubility obtained when, for example, a substrate having a positive hole transporting layer is immersed in a solvent (e.g., tetrahydrofuran) to dissolve a monomer constituting a polymer containing a repeating unit represented by Formulas (1) to (3). Specifically, 10 mg of a polymer constituting a positive hole transporting layer is collected in a sample bottle of 25 ml and then placed into 10 ml of tetrahydrofuran to be irradiated for 5 minutes with ultrasound (25 kHz, 150 W, collector current of 1.5 A; 150 produced by Ultrasonic Engineering Co., Ltd.). When the amount of the polymer having been dissolved in the solution obtained is at most 5 mg, the polymer can be determined to have adequate polymerization degree.

Further, from the viewpoint of preventing recombination of charges, immersion in a solution in which a supporting electrolyte and tert-butylpyridine are dissolved in a solvent may be carried out, if appropriate.

There is a forming method in which a coating liquid containing a polymer is prepared and then the coating liquid is coated on a photoelectric conversion lava. Coating methods used to forming a positive hole transporting layer include, for example, a dipping method, a dripping method, a doctor blade method, a spin coating method, a brush coating method, a spray coating method, and a roll coater method. Further, as a solvent for a coating liquid, for example, organic solvents categorized into the following polar solvent and aprotic solvent can be used. Namely, the polar solvent includes, for example, tetrahydrofuran (THF), butylene oxide, chloroform, cyclohexanone, chlorobenzene, acetone, and alcohols, and the aprotic solvent includes, for example, dimethylformamide (DMF), acetonitrile, dimethoxyethane, dimethylsulfoxide, and hexamethylphosphoric triamide.

Other than the forming method in which a coating liquid containing a polymer is used, also available is a method in which a solution containing a compound having a structure represented by Formula (1), (2), or (3), a polymerization catalyst, and a polymerization rate adjuster is coated on a photoelectric conversion layer or immersion is carried out, followed by polymerization to form a positive hole transporting layer. Conditions for polymerization reaction depends on the compound having a structure represented by Formula (1). (2), or (3), the polymerization catalyst, the type and ratio of a polymerization rate adjuster, and the layer thickness to be formed. In the case of reaction by heating in air, it is preferable that the heating temperature be set at 25° C. to 120° C. and the heating duration be set tor 1 minute to 24 hours.

### Layer Configuration of a Dye-Sensitized Solar Cell

The dye-sensitized solar cell shown in FIG. 1 will be further described.

(Substrate)

A substrate 1 is provided on the light incident direction side of the dye-sensitized solar cell 10 and formed of a material exhibiting excellent optical transparency including glass such as soda glass or a transparent resin material from the viewpoint of providing the dye-sensitized solar cell with strength and of ensuring excellent photoelectric conversion efficiency. In the present invention, in the vicinity of the substrate 1, a UV absorbing layer 11 to absorb light of a wavelength of at most 380 nm is preferably provided so that light having passed through the UV absorbing layer 11 provided in the vicinity of the substrate 1 reaches the photoelectric conversion layer 6.

The optical transmittance of the substrate 1 is preferably at least 10%, more preferably at least 50%, specifically preferably 80% to 100%. Herein, the optical transmittance refers to a total light beam transmittance in the visible light wavelength region determined using a method conforming to the test method of the total light beam transmittance of a transparent plastic material based on JIS K 7361-1 (corresponding to ISO 13468-1).

A substrate 1 usable in the present invention is appropriately selectable from well-known substrates, including a transparent inorganic material such as quartz or glass and the following well-known transparent resin materials.

Specific examples of the transparent resin materials include, for example, polyethylene terephthalate (PET), polyethylene naphthalate (PEN), polyphenylene sulfide (PPS), polylmide (PI), polycarbonate (PC), polystyrene (PS), polypropylene (PP), polybutylene terephthalate (PBT), trimethylene terephthalate, polybutylene naphthalate, polyamideimide, cycloolefin polymers, and styrene-butadiene copolymers. Of the above transparent resin materials, polyethylene terephthalate (PET), polyethylene naphthalate (PEN), polyphenylene sulfide (PPS), and polyimide (PI) are available on the market as those having flexibility, being preferable to produce a flexible dye-sensitized solar cell.

The thickness of the substrate 1 can be appropriately set based on the material and the intended use, and in the case of being constructed of a hard material like a transparent inorganic material such as glass, its average thickness is preferably 0.1 mm to 1.5 mm, more preferably 0.8 mm to 1.2 mm. Further, also in the case of use of a transparent resin material, the same average thickness as for the transparent inorganic material may be set. However, when a flexible transparent, resin material is used, its average thickness is preferably 0.5 μm to 150 μm, more preferably 10 μm to 75 μm.

(First Electrode)

Then, the first electrode 2 is arranged between the substrate 1 and the photoelectric conversion layer 6, and to efficiently feed light to the photoelectric conversion layer 6, those preferably having a light arrival rate of at least 80%, more preferably at least 90%, are used.

The first electrode 2 is formed of a metal material or a metal oxide. Specific examples of the metal material include, for example, platinum, gold, silver, copper, and aluminum. Silver is preferable since those worked into a shape easily exhibiting optical transparency are being supplied in large amounts. For example, a large number of grid pattern films having openings and films in which fine particles or nanowires are dispersed are being supplied. Further, specific examples of the metal oxide include, for example, SnO₂, ZnO, CdO, a CTO-based oxide, In₂O₃, and CdIn₂O₄. Those in which one type or at least 2 types of atom selected from Sn, Sb, F, and Al are doped in any of the metal oxides are preferably used. Of these, conductive metal oxides such as those referred to as ITO in which Sn is doped in In₂O₃, those in which Sb is doped in SnO₂, and those referred to as FTO in which F is doped in SnO₂ are preferable. From the viewpoint of heat resistance, FTO is specifically preferable. Incidentally, the above CTO-based metal oxide includes, for example, CdSnO₃, Cd₂SnO₄, and CdSnO₄.

Further, the first electrode 1 may be provided on the substrate 1. Those in which a first electrode 2 is provided on a substrate are referred to as conductive substrates. The thickness of such a conductive substrate is preferably set at 0.1 mm to 5 mm. The surface resistance of the conductive substrate is preferably at most 50 Ω/cm², more preferably at most 10 Ω/cm².

(Photoelectric Conversion Layer)

Next, the photoelectric conversion layer 6 will be described. The dye-sensitized solar cell 10 shown in FIG. 1 has a photoelectric conversion layer 6, allowed to be adjacent to the above first, electrode 2, to convert light energy such as sunlight into electrical energy. The photoelectric conversion layer 6 contains a semiconductor to which a sensitizing dye is adsorbed, and at a site receiving light having passed through the first electrode 2, between the site and the first electrode 2, electrons are transferred.

Conversion of light energy into electrical energy in the photoelectric conversion layer 6 is carried out based on the following steps. Initially, light having passed through the first electrode 2 enters the photoelectric conversion layer 6 and then the entered light collides with a semiconductor. The light having collided with the semiconductor diffuses into the photoelectric conversion layer 6 via irregular reflection in arbitrary directions and then the diffused light comes in contact with a sensitizing dye to generate electrons and positive holes (holes). The thus-generated electrons move to the first electrode 2. On the basis of such a mechanism, the photoelectric conversion layer 6 converts light energy into electrical energy.

The thickness of the photoelectric conversion layer 6 is not specifically limited However, specifically, the thickness is preferably about 0.1 μm to 50 μm, more preferably about 0.5 μm to 25 μm, specifically preferably about 1 μm to 10 μm. Herein, the thickness of the photoelectric conversion layer 6 is nearly equal to that of a contained semiconductor, and from the viewpoint of element downsizing and production cost reduction, a semiconductor having a layered form is preferably used.

(Semiconductor)

As the semiconductor 5 used in the photoelectric conversion layer 6, a single body such as silicon or germanium, a compound having an atom belonging to group 3 (group 3A) to group 5 (group 5A.) and group 13 (group 3B) to group 15 (group 5B) in the periodic table of the elements, a metal chalcogenide, or a metal nitride is usable. Herein, the metal chalcogenide refers to a compound formed from an atom belonging to group 16 (group 6B) of the periodic table of the elements such as an oxygen atom or sulfur atom referred to as a chalcogen element and a metallic atom, falling under the category of a metal oxide, a metal sulfide, a metal selenide, and a metal telluride.

Specific examples of the metal chalcogenide include, for example, the following compounds.

(1) Metal Oxides

TiO, TiO₂, TiO₂O₃, SnO₂, Fe₂O₃, WO₃, ZnO, and Nb₂O₅

(2) Metal Sulfides

CdS, ZnS, PbS, Bi₂S₃, and CuInS₂

(3) Metal Selenides and Metal Tellurides

CdSe, PbSe, CuInSe₂, and CdTe

Of the above metal chalcogenides, TiO₂, SnO₂, Fe₂O₃, WO₃, ZnO, Nb₂O₅, CdS, and PbSe are preferably used. Of these, TiO₂ and Nb₂O₅ are more preferable and TiO₂ is specifically preferable. Titanium dioxide is specifically preferable because of having excellent electron transportability as well as enhanced sensitivity to light resulting in direct generation of electrons via reception of light by titanium dioxide itself which makes it possible to expect enhanced photoelectric conversion efficiency. Further, since titanium dioxide has a stable crystal structure, degradation over time tends not to occur even with light irradiation under a severe ambience, and thereby a predetermined performance can be stably expressed over a long term.

The crystal structure of titanium dioxide includes an anatase type and a rutile type. In semiconductor materials for dye-sensitized solar cells, usable is any of a material mainly having an anatase type crystal structure, a material mainly having a ruble type crystal structure, and a material mainly having a mixture of both types. Of these, titanium dioxide basing an anatase type crystal structure realizes efficient electron transportability. Further, in the case of mixed use of an anatase type and a rutile type, the mixture ratio of the anatase type and the rutile type is not specifically limited and the ratio may fail within the range of the anatase type: the rutile type=95:5 to 5:95 and the ratio of 80:30 to 20:80 is preferable.

As metal nitrides usable for semiconductors, for example, Ti₃N₄ is representative, and further metal phosphides such as GaP and InP and compounds such as GaAs are employable as semiconductors.

As the semiconductor used for the photoelectric conversion layer 6, any of the above compounds is usable alone and also a plurality thereof are usable in combination. Specific examples in combination of a plurality of these compounds include, for example, a form in which TiO₂ is mixed with Ti₃N₄ at 20% by mass and a complex of ZnO and SnO₂ disclosed in J. Chem. Soc., Chem. Commun. 15 (1999). When a metal oxide or a metal sulfide is combined with a compound other than the above oxide or sulfide, the content of the compound is preferably at most 30% by mass.

As the semiconductor used for the photoelectric conversion layer 6, those surface-treated wife an organic base are usable. In the surface treatment of the semiconductor, a method to immerse a semiconductor in a liquid tank containing an organic base is mainly employed, and when the organic base is liquid, it is used as is and in the case of solid, a solution in which the solid is dissolved in an organic solvent is used. The organic base used in surface treatment includes, for example, diarylamine, triarylamine, pyridine, 4-tert- butylpyridine, polyvinylpyridine, quinoline, and amidine. Of these, pyridine, 4-t-butylpyridine, and polyvinylpyridine are preferable.

From the viewpoint of facilitation of irregular reflection and diffusion of collided light to enhance photoelectric conversion efficiency, the surface of a semiconductor material preferably has a plurality of fine holes (pores). Titanium dioxide described above is expected to exhibit enhanced photoelectric conversion efficiency because of having pores on the surface. Pores of a semiconductor material can be defined, for example, by the ratio of the area of holes occupied per area of the semiconductor particle surface referred to as porosity. Namely, a semiconductor material having appropriate porosity facilitates irregular reflection and diffusion of light, and also the adsorption area of a sensitizing dye adsorbed to the outer surface of the semiconductor material and to the inner surface of pores increases wife an increase in the surface area due to the pores. Thereby, the photoelectric conversion efficiency is further enhanced. The porosity of the semiconductor is not specifically limited, but for example, in the case of titanium dioxide, the porosity is preferably 5% to 90%, more preferably 15% to 80%, specifically preferably 25% to 70%,

(Average Particle Diameter of the Semiconductor Material)

The average particle diameter of the semiconductor 5 is not specifically limited. However, commonly, the diameter is preferably 1 nm to 1 μm, more preferably 5 nm to 50 nm. When the average particle diameter of the semiconductor material is allowed to fall within the range, the uniformity of the semiconductor material is easy to increase in formation of a sol liquid and then due to the enhanced uniformity, the specific surface area of the semiconductor material becomes uniform. Thereby, a sensitizing dye is adsorbed on each semiconductor material at an equal level to contribute to enhancing power generation efficiency.

The photoelectric aversion layer 6 contains a semiconductor 5 and a sensitizing dye 4. The sensitizing dye is adsorbed on foe semiconductor to be used. Adsorption formed between the semiconductor material and the sensitizing dye is realized, for example, by a physical action such as an intermolecular attractive force or electrostatic attractive force or chemical bonding such as covalent bonding or coordinate bonding. The sensitizing dye generates electrons and positive holes (holes) via light reception and actually converts light energy into electrical energy in the photoelectric conversion layer 6. Namely, in the photoelectric conversion layer 6, a region where a sensitizing dye is present is a site functioning as the light reception region to generate electrons and positive holes, and as described above, foe sensitizing dye 4 is adsorbed along the outer surface and the hole inner surface of the semiconductor 5. Then, electrons having been generated by the sensitizing dye 4 move to the semiconductor 5 bonded to the sensitizing dye 4 and further move from the semiconductor 5 to the first electrode 2.

(Sensitizing Dye)

The sensitizing dye 4 is carried on the semiconductor 5 via sensitizing treatment and excited by light, irradiation to emit electrons. In the present invention, a sensitizing dye employable for a dye-sensitized solar cell is used. Such a sensitizing dye employable for a dye-sensitized solar cell includes an organic pigment, a carbon-based pigment, an inorganic pigment, and organic and inorganic dyes.

An organic pigment as the sensitizing dye includes, for example, the following phthalocyanine pigment, azo pigment, quinacridone pigment, and perylene pigment: (1) the phthalocyanine pigment phthalocyanine green and phthalocyanine blue, (2) the azo pigment: fast yellow, disazo yellow, condensed azo yellow, benzimidazolone yellow, dinitroaniline orange, benzimidazolone orange, toluidine red, permanent carmine, permanent red, naphthol red, condensed azo red, benzimidazolone carmine, and benzimidazolone brown, (3) the anthraquinone pigment: anthrapyrimidine yellow and anthraquinonyl red, (4) the quinacridone pigment: quinacridone magenta, quinacridone maroon, quinacridone scarlet, and quinacridone red, and (5) the perylene pigment: perylene red and perylene maroon.

Other than the above organic pigments, the following organic pigments or dyes are usable: namely, an azomethine pigment such as azomethine yellow, a quinophtharone pigment such as quinophtharone yellow, an isoindoline pigment such as isoindoline yellow, an indoline dye and a nitroso pigment such as nickel dioxime yellow.

Also, a perylene pigment such as perylene orange, a pyrrolo-pyrrole pigment such as diketo-pyrrolo-pyrrole red, and a dioxazine pigment such as dioxazine violet are included.

The carbon pigment includes, for example, carbon black, lamp black, furnace black, ivory black, graphite, and fullerene.

Specific examples of a dye usable for the sensitizing dye include, for example, metal complex dyes such as RuL₂Cl₂, RuL₂(CN)₂, ruthenium 535-bis TBA (produced by Solaronics, Inc.), and [Ru₂(NCS)₂]H₂O. Herein, L in RuL₂Cl₂ and RuL₂(CN)₂ represents 2,2-bipyridine or its derivative. Further, in addition to the metal complex dyes, an organic dye such as a cyan dye or an azo dye and a naturally-derived organic dye such as a hibiscus dye, a blackberry dye, a raspberry dye, a pomegranate juice dye, or a chlorophyll dye are usable.

The sensitizing treatment of the semiconductor 4 using a sensitizing dye 4 will be specifically described later in the paragraph of “[2] Formation of a Photoelectric Conversion Layer,”

(Positive Hole Transporting Layer)

For the positive hole transporting layer 7, the positive hole transporting material of the present invention is used.

(Second Electrode)

Next, the second electrode 8 will be described. The second electrode 8 is formed, in a layered (flat plate-like) manner, adjacent to the positive hole transporting layer 7 and the average thickness thereof is appropriately set based on the material and the intended use, being not specifically limited. The second electrode 8 can be formed using a well-known conductive material or semi-conductive material. The conductive material includes, for example, ionically conductive materials, metals such as aluminum, nickel, cobalt, platinum, silver, gold, copper, molybdenum, titanium, and tantalum, alloys containing these, and carbon materials such as graphite. Further, the semi-conductive material includes, for example, p-type semiconductor materials such as triphenyl diamine (monomer and polymer), polyaniline, polypyrrole, polythiophene, and phthalocyanine compounds (e.g., copper phthalocyanine), or derivatives thereof. These conductive materials and semi-conductive materials may be used alone or in combination of at least 2 types thereof to form a second electrode 8.

(Barrier Layer)

The dye-sensitized solar cell 10 shown in FIG. 1 has a barrier layer 3 between the first electrode 2 and the photoelectric conversion layer 6, and the barrier layer 3 prevents short-circuit occurrence. When a barrier layer 3 is provided, the thickness thereof is, for example, about 0.01 μm to 10 μm. The barrier layer is formed using a metal oxide such as titanium oxide or zinc oxide.

(UV Absorbing Layer)

The solar cell of the present invention may have a UV absorbing layer. The UV absorbing layer refers to a layer having “a region absorbing light of a wavelength of at most 380 nm at a position between the light incident surface and a semiconductor located on the surface side. When this UV absorbing layer is provided, photodecomposition of the sensitizing dye can be inhibited and the life time thereof can further be extended.

Further, as specific compound examples, the following specific examples of a benzophenone compound, a benzotriazole compound, a benzoate compound, and a triazine compound are shown but these compounds are not limited to the following: namely, (1) the benzophenone compound: 2,4-dihydroxybenzophenone, 2-hydroxy-4-methoxybenzophenone, and 2-hydroxy-4-n-octoxybenzophenone, (2) the benzotriazole compound: 2-(2H-benzotriazole-2-yl)-4-t-butylphenol, 2-(2′-hydroxy-5′-methylphenyl)benzotriazole, 2-(2′-hydroxy-5′-t-octylphenyl)benzotriazole,2-(3′-t-butyl-2′-hydroxy-5′-methylphenyl)-5-chlorobenzotriazole, 2-(2′-hydroxy-3′,5′-di-t-amylphenyl)benzotriazole, 2-(2′-hydroxy-3′,5′-di-t-butyllphenyl)benzotriazole, 2-[2′-hydroxy-3,5-di(1,1-dimethylbenzyl)phenyl]-2H -benzotriazole, and 2,2′-methylenebis[6-(2H-benzotriazole-2-yl)-4-(1,1,3,3-tetramethylbutyl)phenol)], (3) the benzoate compound: 2,4-di-t-butylphenyl-3,5-di-t-butyl-4-hydroxybenzoate, and (4) the triazine compound: 2-[4,6-bis(2,4-dimethylphenyl)-1,3,5-triazine-2-yl]-5-[(octyl)oxy]phenol and 2-[4,6-diphenyl-1,3,5-triazine-2-yl]-5-[(hexyl)oxy]phenol.

The above organic compounds usable as the UV absorbent are completely dissolved in a solvent, being therefore advantageous in formation of a UV absorbing layer exhibiting enhanced transparency.

(Description of Inorganic Compounds as UV Absorbents)

Further, in formation of a UV absorbing layer 11, inorganic compounds usable as the UV absorbent include, for example, zinc oxide, titanium oxide, iron oxide, cesium oxide, and zirconium oxide. Of these, zinc oxide and titanium oxide are preferable. Further, of the inorganic compounds, zinc oxide is specifically preferable because of forming a UV absorbing layer exhibiting enhanced transparency. Titanium oxide has excellent UV cutting performance, tending, however, to be associated with difficulty in formation of a UV absorbing layer exhibiting enhanced transparency as seen in use of zinc oxide.

The UV absorbing layer formed using any of the above organic or inorganic compounds makes it possible that visible light of at least 400 nm passes at 90% or more, and on the other hand, light having a wavelength of at most 400 nm is cut.

(Description of UV Absorbing Materials)

The UV absorbing layer can be formed by a well-known method such as adhesion of a UV absorbing film or coating of a UV absorbing paint as described above. Commercially available UV absorbing films usable in the present invention include, for example, “SCOTCHTINT Window Film RE87CLIS” (produced by Sumitomo 3M Ltd.). Further, commercially available UV absorbing paints include, for example, fluorine resin coating material “OBBLIGATO” (produced by AGC Coat-Tech Co., Ltd.). Still further, commercially available resin plates and glass plates having UV absorbing performance are employable, including, for example, UV cut glass “UV VERRE” (produced by Asahi Glass Co., Ltd,).

### Production Method of the Dye-Sensitized Solar Cell

One example of the production method of the dye-sensitized solar cell according to the present invention will now be described. The dye-sensitized solar cell according to the present invention can be produced, for example, based on the following steps [1] to [6]. The production method, of the dye-sensitized solar cell according to the present invention is not limited to those in which production is carried out based on the following steps. Production can be carried out based on other well-known methods. Incidentally, in the present invention, a dye-sensitized solar cell is preferably produced via heating treatment to be described in step [6].

[1] Formation of a First Electrode

A substrate made of glass having optical transparency or of a resin having excellent heat resistance, in which both are uniform in thickness, is prepared and then a first electrode is formed on the substrate using a well-known him forming apparatus such as a pulse laser vapor deposition method. Herein, organic materials having excellent heat resistance used for the substrate include, for example, a polyethylene naphthalate (PEN) resin and a polyimide resin.

[2] Formation of a Photoelectric Conversion Layer

Subsequently, on top of the first electrode, a photoelectric conversion layer 6 is formed using a semiconductor material. The photoelectric conversion layer 6 can be formed, for example, in the case of a particle-shaped semiconductor, by coating or spraying the semiconductor onto a substrate on which a first electrode has been formed. Further, in the case of a film semiconductor, formation can be carried out by bonding the semiconductor to a substrate on which a first electrode has been formed. As one of the preferred aspects in formation of the photoelectric conversion layer 6, a forming method in which semiconductor particles are fired is cited. When semiconductor particles are fired to form a photoelectric conversion layer 6, sensitizing treatment for the semiconductor is preferably carried out after firing, especially, before water is adsorbed to the semiconductor after firing. A method to form a photoelectric conversion layer 6 by firing semiconductor particles is described below.

The method for forming a photoelectric conversion layer 6 by firing semiconductor particles is performed, for example, via the following steps:

(1) Preparation of a coating liquid containing semiconductor particles

(2) Coating of the coating liquid containing semiconductor particles and firing treatment

(3) Adsorption treatment of a sensitizing dye to a semiconductor

These are described below.

(1) Preparation of a Coating Liquid Containing Semiconductor Particles

This step is one in which semiconductor particles are placed into a well-known solvent and dispersed to prepare a coating liquid. The concentration of semiconductor particles in the coating liquid is, for example, preferably 0.1% by mass to 70% by mass, more preferably 0.1% by mass to 30% by mass. The semiconductor particles preferably have relatively small particle diameter, for example, those having an average primary particle diameter of 1 nm to 5000 nm are preferably used, more preferably 2 nm to 100 nm.

The solvent for dispersion of semiconductor particles is not specifically limited as long as the semiconductor particles can be dispersed without aggregation, including water, an organic solvent, and a liquid mixture of water and an organic solvent. Specific examples of the organic solvent include, for example, alcohols such as methanol or ethanol, ketones such as acetone, methyl ethyl ketone, or acetylacetone, and hydrocarbons such as n-hexane or cyclohexane.

In the coating liquid, a well-known surfactant or viscosity adjuster can be added as appropriate. Specific examples of the viscosity adjuster include polyols such as polyethylene glycol as representative ones

(2) Coating of the Coating Liquid Containing Semiconductor Particles and Firing Treatment

In this step, the coating liquid having been formed by dispersing semiconductor particles in a solvent is coated on the substrate on which a first electrode is formed, followed by drying to form a semiconductor particle layer. Then, firing treatment is carried out in air or under nitrogen gas atmosphere to fix a semiconductor 5 on the substrate in a layered manner. The semiconductor 5 having been formed in a layered manner is also referred to as a semiconductor layer. In a semiconductor particle layer formed on a substrate via coating, the bonding force to the substrate and the bonding force among semiconductor particles are weak. However, firing treatment enhances the bonding force to the substrate or the bonding force among semiconductor particles to form a strong layer having durability. The thickness of a semiconductor layer formed by firing treatment is preferably at least 10 nm, more preferably 500 nm to 30 μm.

The semiconductor layer forms a strong porous structure via firing treatment. Then, a positive hole transporting material is allowed to be present in voids constituting the porous structure to enhance photoelectric conversion efficiency. In this manner, a semiconductor layer having a porous structure has large actual surface area compared with apparent surface area, which is highly effective for enhancement of performances including photoelectric conversion efficiency. The porosity of the semiconductor layer is, for example, preferably 1% by volume to 90% by volume, more preferably 10% by volume to 80% by volume, specifically preferably 20% by volume to 70% by volume. Voids formed in the semiconductor layer have penetrating properties in the layer thickness direction and porosity can be determined using a common method. A representative determination member for porosity includes, for example, commercially available mercury porosimeter “Shimadzu PORESIZER 9220 (produced by Shimadzu Corp.).”

From the viewpoint of forming a porous structure having porosity, the temperature of firing treatment is preferably in the temperature range of less than 1000° C., more preferably 200° C. to 800° C., specifically preferably 300° C. to 800° C. When a semiconductor layer fired on a resin substrate is formed, it is unnecessary to forcedly carry out firing treatment at 200° C. or more. Instead, pressurization treatment can realize fixing among semiconductor particles or fixing to the substrate. Further, microwaves are usable to heat only the semiconductor without heating the substrate for firing treatment.

To efficiently inject electrons into a semiconductor layer using a sensitizing dye, a semiconductor layer formed via firing treatment can be plated using a chemical or electrochemical method.

(3) Adsorption Treatment of a Sensitizing Dye to a Semiconductor 5

In the sensitizing treatment for the semiconductor 5, a substrate provided with a photoelectric conversion layer (semiconductor layer) in which a semiconductor is formed in a layered manner is immersed in a solution in which a sensitizing dye is dissolved. The total carried amount of the sensitizing dye 4 in the photoelectric conversion layer 6 is preferably 0.01 to 100 mmol/m², more preferably 0.1 to 50 mmol/m², specifically preferably 0.5 to 20 mmol/m².

The sensitizing treatment can employ either of a method to use a single type of sensitizing dye and a method to use plural types of sensitizing dye. For example, when a photoelectric conversion element is used for a solar cell to ensure a wider photoelectrically convertible wavelength range, a method in which a plurality of dyes differing in absorption wavelength are combined is preferably employed.

A solvent to dissolve a sensitizing dye is one to dissolve a sensitizing dye and on the other hand, to dissolve a semiconductor for reaction and an organic solvent is employable therefor. Such an organic solvent includes, for example, a nitrile solvent, an alcohol solvent, a ketone solvent, an ether solvent, and a halogen solvent. These solvents can be used alone or in combination of a plurality of types, including (a) the nitrile solvent: acetonitrile, (b) the alcohol solvent: methanol, ethanol, and n-propanol, (c) the ketone solvent: acetone and methyl ethyl ketone, (d) the ether solvent: diethyl ether, diisopropyl ether, tetrahydrofuran, and 1,4-dioxane, and (e) the halogen solvent: methylene chloride and 1,1,2-trichloroethane.

Of the above solvents, acetonitrile, an acetonitrile/methanol mixed solvent, methanol, ethanol, acetone, methyl ethyl ketone, tetrahydrofuran, and methylene chloride are preferable.

To allow a solution to deeply penetrate a semiconductor layer for adequate advance of adsorption to a semiconductor to sufficiently sensitize the semiconductor, the duration of immersion in a solution containing a sensitizing dye is, for example, preferably 3 hours to 48 hours, more preferably 4 hours to 24 hours at 25° C. Further, the solution can be heated if a contained sensitizing dye is not decomposed, and the solution temperature can be set, for example, at 25° C. to 80° C.

Via the following steps, a photoelectric conversion layer 6 can be produced.

[3] Formation of a Positive Hole Transporting Layer

The present invention makes it possible to form a positive hole transporting layer 7 containing a conductive polymer as the positive hole transporting material and the formed positive hole transporting layer 7 is formed so as to penetrate the photoelectric conversion layer 6.

When the photoelectric conversion layer 6 has voids in its interior, for example, when formation is made by adsorbing a sensitizing dye to a layer having been formed via firing of semiconductor particles, in formation using a liquid positive hole transporting layer material, the photoelectric conversion layer and the positive hole transporting layer do not exist independently, resulting in a layer configuration in which the photoelectric conversion layer is contained in the positive hole transporting layer. Therefore, in the present invention, it is not always necessary for a photoelectric conversion layer containing a semiconductor and a sensitizing dye to coexist with a positive hole transporting layer containing a solid positive hole transporting material independently. A layer attaining a semiconductor and a sensitizing dye and a layer containing a solid positive hole transporting material may be integrated.

[4] Formation of a Second Electrode

A second electrode is formed on the top surface of a positive hole transporting layer. The second electrode can be formed of a second electrode material made of gold using a vapor deposition method, a spattering method, or a printing method.

[5] Formation of a UV Absorbing Layer

The UV absorbing layer means that on the side where light enters the photoelectric conversion layer 6, a UV absorbing layer 11 absorbing UV radiation is provided. “The side where light enters” refers to the side where the substrate 1 and the first electrode 2 are provided. Specific methods for providing a UV absorbing layer 11 include, for example, a method in which a UV absorbing film is bonded to the substrate 1 and a method in which a UV absorbing paint is coated on the substrate 1.

[6] Heat Treatment Operations

As a preferred embodiment when the dye-sensitized solar cell of the present invention is produced, there is cited a method in which at least a photoelectric conversion layer and a positive hole transporting layer are formed, followed by hearing to produce a dye-sensitized solar cell. In the dye-sensitized solar cell thus formed via this heating treatment, no over-time decrease in photoelectric conversion efficiency occurs and thereby the photoelectric conversion efficiency can be stably maintained over a long term.

The reason why in the thus-heated dye-sensitized solar cell, the initial photoelectric conversion efficiency is stably maintained over a long term is unclear. However, the following is conceivable: namely, it is thought that conductive polymer chains forming a positive hole transporting layer form a further closed packed state by use of thermal energy during heating treatment Then, via high-density packing of the conductive polymer chains, even when the occasion where sunlight is received is increased, the intermolecular distance between the conductive polymer chains is easily maintained, and thereby the initial photoelectric conversion efficiency is thought to be stably maintained over a long term.

The temperature of heating treatment is preferably 70° C. to 150° C., specifically preferably 80° C. to 120° C. Further, the treatment duration is preferably 1 minute to 30 minutes, more preferably 5 minutes to 15 minutes.

Via the above steps, the dye-sensitized solar cell according to the present invention can be produced.

### EXAMPLES

With reference to examples, the present invention will now be described.

1. Production of Dye-Sensitized Solar Cells 1 to 40

1-1. Production of Dye-Sensitized Solar Cell 1 (Example 1)

Via the following procedures, dye-sensitized solar cell 1 having a configuration shown in FIG. 1 was produced.

(1) Preparation of a Substrate

A soda glass available on the market having dimensions of 30 mm high×35 mm long×2.5 mm thick was prepared and then the substrate was immersed in a washing liquid of 85° C. containing a liquid mixture of sulfuric acid and hydrogen peroxide solution, followed by washing to clean the surface.

(2) Formation of a First Electrode and a Barrier Layer

Using a film forming apparatus employing a vapor deposition method, on the soda glass substrate, a first electrode made of FTO (fluorine-doped tin oxide) was formed in which its size was 30 mm high×35 mm long×1 μm thick and its sheet resistance was 20 Ω/□. Onto the substrate on which the first electrode had been formed, a solution in which 1.2 ml of tetrakis isopropoxy titanium and 0.8 ml of acetylacetone were dissolved in 18 ml of ethanol was dipped, followed by film formation using a spin coating method and heating at 450° C. for 8 minutes to form a titanium oxide-made barrier layer of a thickness of 40 nm on the first electrode.

(3) Formation of a Photoelectric Conversion Layer

Then, on top of the barrier layer and the first electrode of a FTO thin film, a photoelectric conversion layer incorporating titanium oxide was formed. Namely,

initially, an anatase-type titanium dioxide paste (average primary particle diameter: 18 nm (microscopic observation average), ethyl cellulose dispersion) was coated on the soda glass substrate on which the barrier layer and foe first electrode had been formed using a screen printing method to give a coating area of 25 mm². After coating, firing treatment was carried at 200° C. for 10 minutes and then at 500° C. for 15 minutes to form a titanium dioxide thin film of a thickness of 2.5 μm. The titanium dioxide thin film had a porous structure, having voids.

Next, as the sensitizing dye having the following structure was dissolved in a mixed solvent of acetonitrile: t-butyl alcohol=1:1 to prepare 5×10⁻⁴ mol/L of a solution of

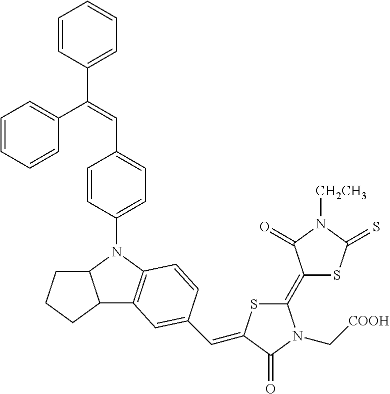 [SMILES: CCN1C(=O)/C(=c2\s/c(=C\c3ccc4c(c3)C3CCCC3N4c3ccc(C=C(c4ccccc4)c4ccccc4)cc3)c(=O)n2CC(=O)O)SC1=S]

The glass substrate on which titanium dioxide had been coated and fired was immersed in the above solution at room temperature for 3 hours and thereby the dye was adsorbed thereon for sensitizing treatment. In this manner, a photoelectric conversion layer was formed.

(4) Formation of a Positive Hole Transporting Layer

The glass substrate on which the photoelectric conversion layer had been formed was immersed in an acetonitrile solution containing the following, followed by electrolytic polymerization to form a positive hole transporting layer containing a conductive polymer, being solvent-insoluble, on the photoelectric conversion layer.

| | |
|---|---|
| M1-1 | 0.005 mol/L |
| M1-4 | 0.005 mol/L |
| Li[(CF₃SO₂)₂N] | 0.1 mol/L |

In the electrolytic polymerization, the first electrode and a platinum wire were used as the working electrode and the opposite electrode, respectively, and Ag/Ag⁺ (AgNO₃: 0.01 mol) was used as the reference electrode. Then, the hold voltage was set at −0.16 V. While light (as the light source, a xenon lamp was used at an optical density of 22 mW/m² and light of a wavelength of at most 430 nm was cut) was irradiated from the photoelectric conversion layer direction, the voltage was maintained for 30 minutes.

Via the above procedures, a positive hole transporting layer was formed and then the glass substrate was washed wife acetonitrile and dried. Thereafter, the glass substrate was immersed for 10 minutes in an acetonitrile solution containing the following, followed by natural drying to produce a positive hole transporting layer.

| | |
|---|---|
| Li[(CF₃SO₂)₂N] | 1.5 × 10⁻² mol/L |
| t-Butylpyridine | 5 × 10⁻² mol/L |

(5) Formation of a Second Electrode

Subsequently, on the positive hole transporting layer, gold was deposited at a thickness of 60 nm using a vacuum vapor deposition method for formation of a second electrode to produce dye-sensitized solar cell 1 of Example 1.

1-2. Production of Dye-Sensitized Solar Cells 2 to 36 (Examples 2 to 36)

Dye-sensitized solar cells 2 to 36 were produced in the same manner as in production of above dye-sensitized solar cell 1 except that instead of compounds M1-1 and M1-4 used to form the positive hole transporting layer, the compounds shown in Table 1 were used to produce a positive hole transporting layer.

1-3. Production of Dye-Sensitized Solar Cells 37 to 40 (Examples 37 to 40)

Further, those having the same configuration as dye-sensitized solar cell 14 in which the heating temperature was set at 60° C., 70° C., and 100° C. and then 15-minute hearing treatment was carried out at each temperature were produced as dye-sensitized solar cells 37 to 40.

2. Production of Comparative Dye-Sensitized Solar Cells 1 to 3 (Comparative Examples 1 to 3)

Comparative dye-sensitized solar cells 1 to 3 were produced in the same manner as in production of dye-sensitized solar cell 1 except that as the compounds used to form a positive hole transporting layer, the compound shown in Table 1 was used.

TABLE 1

| | Compound No. | Compound No. | |
|---|---|---|---|
| Dye-Sensitized | of Formulas | of Formulas | Heating |
| Solar Cell No. | (1) to (3) | (1) to (3) | Treatment |
| 1 | M1-1 | M1-4 | no |
| 2 | M1-7 | M3-4 | no |
| 3 | M1-21 | M2-18 | no |
| 4 | M1-19 | M2-3 | no |
| 5 | M1-16 | M2-16 | no |
| 6 | M1-30 | M2-25 | no |
| 7 | M1-31 | M3-18 | no |
| 8 | M1-28 | M2-30 | no |
| 9 | M1-15 | M2-13 | no |
| 10 | M1-19 | M2-8 | no |
| 11 | M1-31 | M2-30 | no |
| 12 | M1-13 | M2-29 | no |
| 13 | M1-27 | M3-18 | no |
| 14 | M1-15 | M1-16 | no |
| 15 | M1-21 | M1-20 | no |
| 16 | M2-13 | M2-17 | no |
| 17 | M1-28 | M1-31 | no |
| 18 | M1-33 | M1-32 | no |
| 19 | M1-40 | M1-34 | no |
| 20 | M2-25 | M2-29 | no |
| 21 | M1-13 | M1-16 | no |
| 22 | M1-13 | M1-21 | no |
| 23 | M1-24 | M1-19 | no |
| 24 | M2-11 | M2-17 | no |
| 25 | M1-25 | M1-28 | no |
| 26 | M1-25 | M1-33 | no |
| 27 | M2-21 | M2-29 | no |
| 28 | M1-13 | M1-24 | no |
| 29 | M1-23 | M1-24 | no |
| 30 | M2-11 | M2-12 | no |
| 31 | M3-7 | M3-8 | no |
| 32 | M1-25 | M1-36 | no |
| 33 | M1-25 | M1-26 | no |
| 34 | M2-21 | M2-22 | no |
| 35 | M2-21 | M2-23 | no |
| 36 | M3-11 | M3-12 | no |
| 37 | M1-15 | M1-16 | 60° C./15 min |
| 38 | M1-15 | M1-16 | 70° C./15 min |
| 39 | M1-15 | M1-16 | 100° C./15 min |
| 40 | M1-15 | M1-16 | 110° C./15 min |
| Comparative | M1-25 | none | no |
| Example 1 | | | |
| Comparative | M2-21 | none | no |
| Example 2 | | | |
| Comparative | M3-12 | none | no |
| Examglep | | | |

3. Evaluation Experiments

With regard to dye-sensitized solar cells 1 to 40 of the present invention and comparative dye-sensitized solar cells 1-3 produced via the above procedures, enforced degradation tests were conducted via heating treatment in the following manner to evaluate the stable maintenance performance over time of the photoelectric conversion efficiency. Namely, the photoelectric conversion efficiency η of each of the dye-sensitized solar cells was measured and calculated via a method described below. Subsequently, each dye-sensitized solar cell was heated at 85° C., followed by being placed into an oven to be allowed to stand for 24 hours for hearing treatment. Then, the photoelectric conversion efficiency η′ of each dye-sensitized solar ceil after heating treatment was measured and calculated to calculate the decreasing rate of the photoelectric conversion efficiency η prior to and after the heating treatment for evaluation.

Herein, with regard to dye-sensitized solar cells 1 to 40 of the present invention and comparative dye-sensitized solar cells 1 to 3 (1 to 3 for comparison) produced via the above procedures, those, in which the photoelectric conversion efficiency η was measured prior to and after the heating treatment to calculate the decreasing rate of the photoelectric conversion efficiency η, were designated as Examples 1 to 40 and Comparative Examples 1 to 3.

The photoelectric conversion efficiencies η and η′ are measured and calculated via the following procedures. Namely, pseudo-sunlight of an irradiation intensity of 100 mW/cm2 formed using commercially available solar simulator “WXS-85-H (produced by Wacom Electric Co., Ltd.)” is irradiated to each dye-sensitized solar cell at room temperature (at 20° C.). The pseudo-sunlight is formed by allowing xenon lamp light to pass through an AM filter (AM 1.5) using the solar simulator.

Then, the current-voltage characteristics of each dye-sensitized solar cell during irradiation of the pseudo-sunlight are measured using a commercially available I-V tester to calculate form factor FF from short-circuit current density Jsc and open voltage Voc, as well as a current-voltage characteristic graph. These values are substituted into a calculation expression described later to calculate the photoelectric conversion efficiency η. Herein, the hearing treatment is carried out in an oven in the dark.

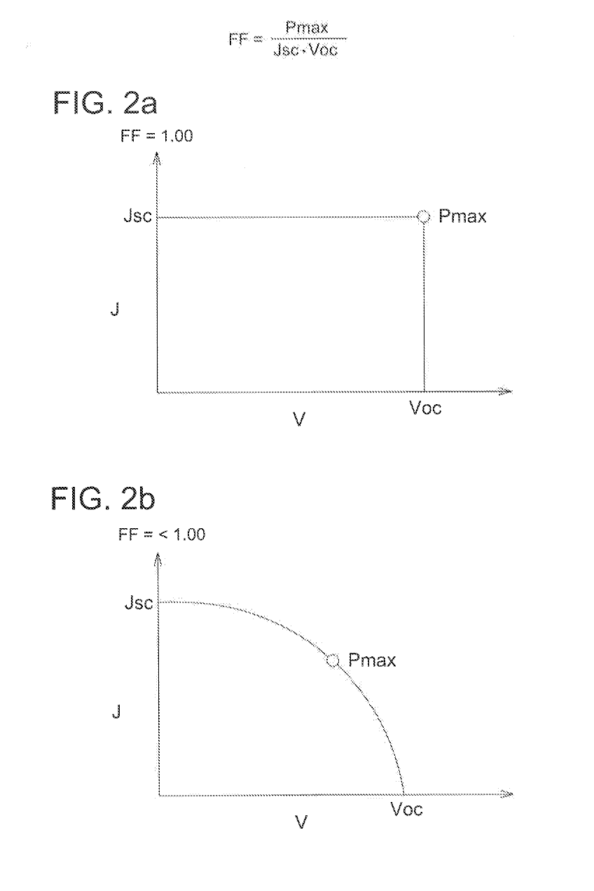

The open voltage Voc refers to a voltage value when a voltage is loaded to a dye-sensitized solar cell and then the state where no current flows is created. The short-circuit current density Jsc refers to the value of current per cm² flowing in the state where no voltage is loaded to the dye-sensitized solar cell. Further, the form factor FF is a value represented by the numerical value of the locus shown in a current-voltage characteristic graph obtained when photoelectric conversion efficiency is measured to be described below, being a value obtained by dividing irradiation intensity Po by the product of short-circuit current density Jsc and open voltage. Voc. FIG. 2a and FIG. 2b show the calculation expression of form factor FF and examples of the locus of a current-voltage characteristic graph when form factor FF is 1.00 and less than 1.00.

Further, photoelectric conversion efficiency η is calculated by the following expression. Namely, when the irradiation intensity and the short-circuit current density of each dye-sensitized solar cell are designated as Po (100 mW/cm²) and Jsc (mA/cm²), respectively, and then the open voltage and the form factor are designated as Voc (V) and FF, respectively, the photoelectric conversion efficiency η is calculated by the following expression.

η(%)=[(Jsc×Voc×FF)Po]×100

The photoelectric conversion efficiency η′ after heating treatment is also calculated by the above expression.

Incidentally, in this evaluation, pseudo-sunlight of an irradiation intensity Po of 100 mW/cm²is irradiated using the above solar simulator.

Then, the decreasing rate Δ_{η}(%) of the photoelectric conversion efficiency prior to and after heating treatment is calculated by the following expression.

Δ_{η}(%)=[(η−η′)/η]×100

In this evaluation, those were evaluated to be acceptable in which both of the photoelectric conversion efficiency η prior to heating treatment and tire photoelectric conversion efficiency η′ thereafter were at least 4.00% and also the decreasing rate Δη of the photoelectric conversion efficiency was at most 5.0%. The results are shown in following Tables 2 and 3.

TABLE 2

| | | Prior to Heating (Enforced Degradation Test) | | | | After Heating (Enforced Degradation Test) | | | | |
|---|---|---|---|---|---|---|---|---|---|---|
| | Dye-Sensitized | Voc | Jsc | | η | Voc | Jsc | | η′ | Δη |
| Example | Solar Cell No. | (mV) | (mA/cm²) | FF | (%) | (mV) | (mA/cm²) | FF | (%) | (%) |
| Example 1 | 1 | 855 | 7.18 | 0.760 | 4.67 | 845 | 7.11 | 0.754 | 4.53 | 3.0 |
| Example 2 | 2 | 858 | 7.18 | 0.767 | 4.73 | 848 | 7.10 | 0.762 | 4.59 | 3.0 |
| Example 3 | 3 | 850 | 7.11 | 0.752 | 4.54 | 841 | 7.00 | 0.747 | 4.40 | 3.1 |
| Example 4 | 4 | 855 | 7.15 | 0.753 | 4.60 | 845 | 7.07 | 0.747 | 4.46 | 3.0 |
| Example 5 | 5 | 856 | 7.17 | 0.761 | 4.67 | 845 | 7.09 | 0.757 | 4.53 | 3.0 |
| Example 6 | 6 | 857 | 7.16 | 0.760 | 4.66 | 846 | 7.08 | 0.755 | 4.52 | 3.0 |
| Example 7 | 7 | 858 | 7.15 | 0.762 | 4.67 | 847 | 7.08 | 0.754 | 4.52 | 3.2 |
| Example 8 | 8 | 858 | 7.16 | 0.763 | 4.69 | 848 | 7.09 | 0.756 | 4.55 | 3.0 |
| Example 9 | 9 | 854 | 7.17 | 0.761 | 4.66 | 844 | 7.10 | 0.755 | 4.52 | 3.0 |
| Example 10 | 10 | 852 | 7.13 | 0.757 | 4.60 | 842 | 7.04 | 0.752 | 4.46 | 3.0 |
| Example 11 | 11 | 856 | 7.16 | 0.761 | 4.66 | 845 | 7.09 | 0.757 | 4.52 | 3.0 |
| Example 12 | 12 | 857 | 7.16 | 0.763 | 4.68 | 846 | 7.10 | 0.755 | 4.53 | 3.2 |
| Example 13 | 13 | 853 | 7.15 | 0.755 | 4.60 | 844 | 7.06 | 0.749 | 4.46 | 3.0 |
| Example 14 | 14 | 852 | 7.14 | 0.758 | 4.61 | 843 | 7.05 | 0.751 | 4.46 | 3.3 |
| Example 15 | 15 | 836 | 7.01 | 0.755 | 4.42 | 825 | 6.91 | 0.750 | 4.28 | 3.2 |
| Example 16 | 16 | 851 | 6.98 | 0.756 | 4.49 | 840 | 6.89 | 0.750 | 4.34 | 3.3 |
| Example 17 | 17 | 850 | 7.15 | 0.765 | 4.65 | 836 | 7.09 | 0.758 | 4.49 | 3.4 |
| Example 18 | 18 | 852 | 7.11 | 0.756 | 4.58 | 840 | 7.03 | 0.750 | 4.43 | 3.3 |
| Example 19 | 19 | 827 | 7.18 | 0.725 | 4.30 | 819 | 7.08 | 0.718 | 4.16 | 3.3 |
| Example 20 | 20 | 840 | 7.15 | 0.739 | 4.44 | 828 | 7.04 | 0.736 | 4.29 | 3.4 |
| Example 21 | 21 | 852 | 7.13 | 0.751 | 4.56 | 843 | 7.02 | 0.745 | 4.41 | 3.3 |
| Example 22 | 22 | 831 | 7.03 | 0.715 | 4.18 | 813 | 6.99 | 0.709 | 4.03 | 3.6 |
| Example 23 | 23 | 825 | 7.22 | 0.712 | 4.24 | 812 | 7.12 | 0.708 | 4.09 | 3.5 |
| Example 24 | 24 | 850 | 7.13 | 0.748 | 4.53 | 839 | 7.04 | 0.742 | 4.38 | 3.3 |
| Example 25 | 25 | 833 | 6.97 | 0.731 | 4.25 | 822 | 6.92 | 0.720 | 4.10 | 3.5 |

TABLE 3

| | | Prior to Heating (Enforced Degradation Test) | | | | After Heating (Enforced Degradation Test) | | | | |
|---|---|---|---|---|---|---|---|---|---|---|
| | Dye-Sensitized | Voc | Jsc | | η | Voc | Jsc | | η′ | Δη |
| Example | Solar Cell No. | (mV) | (mA/cm²) | FF | (%) | (mV) | (mA/cm²) | FF | (%) | (%) |
| Example 26 | 26 | 825 | 7.15 | 0.706 | 4.16 | 810 | 7.05 | 0.702 | 4.01 | 3.6 |
| Example 27 | 27 | 840 | 7.00 | 0.728 | 4.28 | 833 | 6.91 | 0.717 | 4.13 | 3.5 |
| Example 28 | 28 | 826 | 7.03 | 0.722 | 4.19 | 814 | 6.94 | 0.717 | 4.05 | 3.3 |
| Example 29 | 29 | 850 | 7.15 | 0.743 | 4.52 | 840 | 7.05 | 0.738 | 4.37 | 3.3 |
| Example 30 | 30 | 847 | 6.99 | 0.741 | 4.39 | 835 | 6.87 | 0.736 | 4.22 | 3.9 |
| Example 31 | 31 | 843 | 7.16 | 0.748 | 4.51 | 830 | 7.06 | 0.742 | 4.35 | 3.5 |
| Example 32 | 32 | 835 | 7.11 | 0.721 | 4.28 | 822 | 7.02 | 0.716 | 4.13 | 3.5 |
| Example 33 | 33 | 828 | 7.10 | 0.709 | 4.17 | 809 | 7.06 | 0.704 | 4.02 | 3.6 |
| Example 34 | 34 | 852 | 6.89 | 0.746 | 4.38 | 839 | 6.80 | 0.739 | 4.22 | 3.7 |
| Example 35 | 35 | 856 | 7.17 | 0.760 | 4.66 | 838 | 7.07 | 0.755 | 4.47 | 4.1 |
| Example 36 | 36 | 855 | 7.18 | 0.759 | 4.66 | 839 | 7.09 | 0.754 | 4.49 | 3.6 |
| Example 37 | 37 | 850 | 7.11 | 0.752 | 4.54 | 841 | 7.00 | 0.747 | 4.40 | 3.1 |
| Example 38 | 38 | 857 | 7.16 | 0.760 | 4.66 | 846 | 7.08 | 0.755 | 4.52 | 3.0 |
| Example 39 | 39 | 853 | 7.15 | 0.755 | 4.60 | 844 | 7.06 | 0.749 | 4.46 | 3.0 |
| Example 40 | 40 | 836 | 7.01 | 0.755 | 4.42 | 825 | 6.91 | 0.750 | 4.28 | 3.2 |
| Comparative | 1 for comparison | 840 | 7.02 | 0.748 | 4.41 | 810 | 6.35 | 0.705 | 3.62 | 17.8 |
| Example 1 | | | | | | | | | | |
| Comparative | 2 for comparison | 843 | 7.04 | 0.745 | 4.42 | 814 | 6.02 | 0.708 | 3.47 | 21.5 |
| Example 2 | | | | | | | | | | |
| Comparative | 3 for comparison | 836 | 7.00 | 0.740 | 4.33 | 799 | 6.32 | 0.708 | 3.58 | 17.4 |
| Example 3 | | | | | | | | | | |

As shown in Tables 2 and 3, the results confirmed that each of Examples 1 to 36 having evaluated a dye-sensitized solar cell in which as the positive hole transporting material, a conductive polymer obtained from at least 2 types of compound having a structure represented by Formula (1), (2), or (3) was used exhibited enhanced photoelectric conversion efficiency. Especially, those employing a polythiophene formed via polymerization of a compound having a specific side-chain structure as the positive hole transporting material were confirmed to exhibit specifically enhanced photoelectric conversion efficiency and further to exhibit enhanced photoelectric conversion efficiency even after heating treatment of 85° C., resulting in stable maintenance of the photoelectric conversion efficiency at a high level. Further, the results confirmed that in Examples 37 to 40, the photoelectric conversion efficiency was stably maintained at a high level even after heating treatment.

Comparative Examples 1 to 3 in which a polythiophene having no structure specified in the present invention was used as the positive hole transporting material exhibited significantly small photoelectric conversion efficiency, compared with Examples 1 to 40. Further, in the solar cells of Comparative Examples 1 to 3, cracks were confirmed to occur in the photoelectric conversion layer. However, in the solar cells of the present invention of Examples 1 to 40, no crack occurrence was confirmed.

1. A dye-sensitized solar cell having at least a substrate, a first electrode, a photoelectric conversion layer containing a semiconductor and a sensitizing dye, a positive hole transporting layer containing a solid positive hole transporting material, and a second electrode, wherein the positive hole transporting material contains a polythiophene-based polymer which is a conductive polymer formed via copolymerization of at least 2 compounds having a structure represented by Formula (1), (2), or (3), 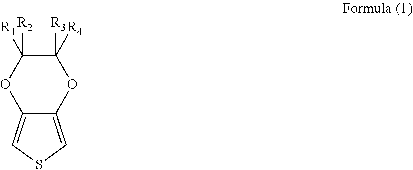
wherein, R₁ to R₄ individually represents a hydrogen atom, a halogen atom, an alkyl group, a cycloalkyl group, an alkoxy group, a polyethylene oxide group, or an aryl group; any of the groups may be substituted, and R₁ to R₄ may be same or different; and the thiophene ring may have a substituent, 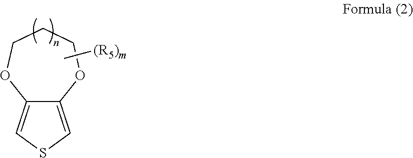
wherein, R₅ represents a hydrogen atom, a halogen atom, an alkyl group, an alkoxy group, a polyethylene oxide group, or an aryl group; any of the groups may be substituted; n represents an integer of 1 or 2, and m represents an integer of 2n+4; and the thiophene ring may have a substituent, 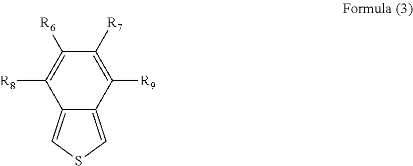
wherein R₆ to ₉ individually represents a hydrogen atom, a halogen atom, an alkyl group, an alkoxy group, a polyethylene oxide group, or an aryl group, any of the groups may be substituted; and R₆ to R₉ may be same or different; and the thiophene ring may have a substituent.

2. The dye-sensitized solar cell of claim 1, wherein at least one of R₁ to R₄ in a compound having the structure represented by Formula (1) is an alkyl group or a cycloalkyl group having 6 to 14 carbon atoms, an aryl group having at least 6 carbon atoms, or an alkyl group having an oxyethylene group.

3. The dye-sensitized solar cell of claim 2, wherein at least one of R₁ to R₄ is an alkyl group having 6 to 14 carbon atoms or an aryl group having at least 6 carbon atoms.

4. The dye-sensitized solar cell of claim 3, wherein at least one of R₁ to R₄ is an alkyl group having 6 to 14 carbon atoms.

5. The dye-sensitized solar cell of claim 1, wherein the substituent of the thiophene ring of Formula (1) is a halogen atom.

6. The dye-sensitized solar cell of claim 5, wherein the substituent of the thiophene ring of Formula (1) is a bromine atom.

7. The dye-sensitized solar cell of claim 1, wherein n in Formula (2) is 1.

8. The dye-sensitized solar cell of claim 7, wherein R₅ in the compound having the structure represented by Formula (2) is a hydrogen atom, an alkyl group or a cycloalkyl group having 6 to 14 carbon atoms, an aryl group having at least 6 carbon atoms, or an alkyl, group having an oxyethylene group.

9. The dye-sensitized solar cell of claim 8, wherein R₅ is a hydrogen atom, an alkyl group having 6 to 14 carbon atoms or an aryl group having at least 6 carbon atoms.

10. The dye-sensitized solar cell of claim 9, wherein R₅ is a hydrogen atom, an alkyl group having 6 to 14 carbon atoms or an aryl group having at least 6 carbon atoms.

11. The dye-sensitized solar cell of claim 10, wherein R₅ is a hydrogen atom, an alkyl group having 6 to 14 carbon atoms.

12. The dye-sensitized solar cell of claim 1, wherein the substituent of the thiophene ring of Formula (2) is a halogen atom.

13. The dye-sensitized solar cell of claim 12, wherein the substituent of the thiophene ring of Formula (2) is a bromine atom.

14. The dye-sensitized solar cell of claim 1, wherein at least one of R₆ to R₉ in a compound having the structure represented by Formula (3) is an alkyl or a cycloalkyl group having 6 to 14 carbon atoms, an aryl group having at least 6 carbon atoms, or an alkyl group having an oxyethylene group.

15. The dye-sensitized solar ceil of claim 14, wherein at least one of R₆ to R₉ is an alkyl group having 6 to 14 carbon atoms and an aryl group having at least 6 carbon atoms.

16. The dye-sensitized solar cell of claim 15, wherein at least one of R₆ to R₉ is an alkyl group having 6 to 14 carbon atoms.

17. The dye-sensitized solar cell of claim 1, wherein the substituent of the thiophene ring of Formula (3) is a halogen atom.

18. The dye-sensitized solar cell of claim 17, wherein the substituent of the thiophene ring of Formula (3) is a bromine atom.
